(19) United States
(12) Patent Application Publication
(10) Pub. No.: US 2024/0294013 A1
(43) Pub. Date: Sep. 5, 2024

(54) LIQUID JETTING DEVICE, JETTING STATE EVALUATION METHOD, INFORMATION PROCESSING APPARATUS, AND MANUFACTURING METHOD OF PRINT SUBSTRATE

(71) Applicant: FUJIFILM Corporation, Tokyo (JP)

(72) Inventor: Tadashi KYOSO, Kanagawa (JP)

(73) Assignee: FUJIFILM Corporation, Tokyo (JP)

(21) Appl. No.: 18/661,682

(22) Filed: May 12, 2024

Related U.S. Application Data
(63) Continuation of application No. PCT/JP2022/039846, filed on Oct. 26, 2022.

(30) Foreign Application Priority Data
Nov. 29, 2021 (JP) 2021-193105

(51) Int. Cl. B41J 2/175; B41J 2/14

(52) U.S. Cl. CPC B41J 2/175; B41J 2/14201

(57) ABSTRACT

The presently disclosed technology can evaluate a jetting state of a liquid jetting head using a transparent metal complex ink. The liquid jetting device includes a liquid jetting head that jets the metal complex ink, a relative moving mechanism that relatively moves the liquid jetting head and a substrate, an exposure machine that exposes the metal complex ink applied on the substrate, and at least one processor, in which the at least one processor forms a first pattern on the substrate by causing the metal complex ink to be jetted from the liquid jetting head, acquires a reading result obtained by reading the first pattern using an observation device after exposing the first pattern using the exposure machine, and evaluates the jetting state of the liquid jetting head from the reading result.

### CROSS-REFERENCE TO RELATED APPLICATIONS

The present application is a Continuation of PCT International Application No. PCT/JP2022/039846 filed on Oct. 26, 2022 claiming priority under 35 U.S.C § 119(a) to Japanese Patent Application No. 2021-193105 filed on Nov. 29, 2021. Each of the above applications is hereby expressly incorporated by reference, in its entirety, into the present application.

### BACKGROUND OF THE INVENTION

### 1. Field of the Invention

The present disclosure relates to a liquid jetting device, a jetting state evaluation method, an information processing apparatus, a manufacturing method of a print substrate.

### 2. Description of the Related Art

JP2005-224990A describes a jetting failure detection method for detecting a jetting failure of a transparent ink in a case of performing image recording by jetting a basic color ink and a transparent ink from a recording head with respect to a recording medium. In the jetting failure detection method, the transparent ink is mixed with an infrared absorber that absorbs infrared light to create color, the transparent ink mixed with the infrared absorber is jetted from the recording head, and a landing state of the transparent ink is visually detected by irradiating the transparent ink landed on the surface of the recording medium with infrared light.

JP2011-083916A describes, in a liquid jetting device using an ultraviolet (UV) ink containing a photopolymerization initiator, a method of detecting a defective nozzle of a clear ink head using a property that a polymerization initiator containing a clear ink turns yellow due to UV irradiation.

### SUMMARY OF THE INVENTION

In the method described in JP2005-224990A, it is necessary for the infrared absorber which is a component originally unnecessary to be input into an ink, and there is a concern of deteriorating ink characteristics. In addition, in a case where the method described in JP2005-224990A is to be automated, sensing using infrared light is necessary, but an image sensor that is capable of sensing a visible light region is widely distributed, and it is difficult to automate the detection method using infrared light.

In the method described in JP2011-083916A, in order to turn the polymerization initiator yellow, it is necessary to perform exposure by setting irradiation energy of ultraviolet light (UV light) to irradiation energy higher than irradiation energy necessary for original UV curing. For this reason, it is necessary to set the capacity of a UV exposure machine to an output higher than a level necessary for the original UV curing or more, leading to an increase in costs of the device. In addition, the method described in JP2011-083916A cannot be applied to a transparent ink or the like that does not contain a polymerization initiator contributing to yellowing.

The present disclosure is devised in view of such circumstances, and an object thereof is to provide a liquid jetting device, a jetting state evaluation method, an information processing apparatus, and a manufacturing method of a print substrate to which the evaluation technique is applied, which can evaluate a jetting state of a liquid jetting head using a transparent metal complex ink.

According to an aspect of the present disclosure, there is provided a liquid jetting device comprising a liquid jetting head that jets a metal complex ink, a relative moving mechanism that relatively moves the liquid jetting head and a substrate, an exposure machine that exposes the metal complex ink applied on the substrate, and at least one processor, in which the at least one processor is configured to form a first pattern on the substrate by causing the metal complex ink to be jetted from the liquid jetting head, acquire a reading result obtained by reading the first pattern using an observation device after exposing the first pattern using the exposure machine, and evaluate a jetting state of the liquid jetting head from the reading result.

According to the present aspect, by exposing the first pattern formed using the transparent metal complex ink, the first pattern after exposure is brought into a state of being readable using the observation device. The at least one processor can evaluate the jetting state of the liquid jetting head based on the reading result of the first pattern by the observation device.

As the “liquid jetting head”, various jetting types are applicable. The term “jetting” can include meanings such as spraying, coating, and flowing down.

In the liquid jetting device according to another aspect of the present disclosure, the first pattern may be a test pattern for inspecting the jetting state of the liquid jetting head.

In the liquid jetting device according to still another aspect of the present disclosure, an exposure amount of the first pattern by the exposure machine may be less than 500 mJ/cm². By using a minimum required exposure machine with which the exposure amount necessary for reading the first pattern can be obtained, an increase in costs can be suppressed. In addition, by adopting the minimum required exposure machine, an increase in power consumption can be suppressed, and diffusion of leakage light to an edge part of the liquid jetting head can be suppressed.

In the liquid jetting device according to still another aspect of the present disclosure, an exposure amount of the first pattern by the exposure machine may be 300 mJ/cm² or less.

In the liquid jetting device according to still another aspect of the present disclosure, at least one processor may be configured to form a second pattern different from the first pattern by causing the metal complex ink to be jetted from the liquid jetting head.

In the liquid jetting device according to still another aspect of the present disclosure, the second pattern may be a user pattern that is a pattern required for printing by a user.

In the liquid jetting device according to still another aspect of the present disclosure, an exposure amount of the first pattern by the exposure machine may be configured to be larger than an exposure amount of the second pattern by the exposure machine. According to the present aspect, by adopting the minimum required exposure machine that performs necessary exposure on the second pattern, an increase in costs and power consumption can be suppressed, and diffusion of leakage light to the edge part of the liquid jetting head can also be suppressed.

In the liquid jetting device according to still another aspect of the present disclosure, in exposure of the second pattern by the exposure machine, an exposure amount may be ⅕ of an exposure amount of the first pattern by the exposure machine or less. In a subsequent step or the like, processing such as further exposure can be performed on the second pattern, and processing of the metal complex ink can be performed with a high degree of freedom.

In the liquid jetting device according to still another aspect of the present disclosure, exposure of the second pattern by the exposure machine may be an exposure amount to an extent that spread of the metal complex ink on the substrate is capable of being suppressed.

In the liquid jetting device according to still another aspect of the present disclosure, an exposure amount of the second pattern by the exposure machine may be 30 mJ/cm² or more and 100 mJ/cm² or less.

In the liquid jetting device according to still another aspect of the present disclosure, the exposure machine may be configured to include a first exposure machine and a second exposure machine, the first exposure machine may be configured to maintain the same output state and to expose both the first pattern and the second pattern, and the second exposure machine may be configured to change the output state and to expose only the first pattern among the first pattern and the second pattern. According to the present aspect, an exposure amount necessary for the second pattern can be easily controlled.

In the liquid jetting device according to still another aspect of the present disclosure, the second pattern may be configured to be formed on the same substrate as the substrate on which the first pattern is formed.

In the liquid jetting device according to still another aspect of the present disclosure, the first pattern may be configured to be formed in a case of the relative movement before formation of the second pattern. According to the present aspect, since the second pattern is formed after forming the first pattern, jetting of an ink for forming the first pattern also serves as dummy jetting (preliminary jetting) as a measure against ink thickening. Accordingly, before forming the second pattern, a thickened ink in the liquid jetting head is discharged, and the second pattern can be well formed.

In the liquid jetting device according to still another aspect of the present disclosure, the first pattern may be configured to be formed in a region of the substrate, which is excised in a case of cutting the substrate into individual pieces. According to such an aspect, it is not necessary to ensure a wasted space for forming the first pattern on the substrate, and the substrate can be effectively used.

In the liquid jetting device according to still another aspect of the present disclosure, a first substrate that is the substrate on which the first pattern is formed and a second substrate on which the second pattern is formed may be individual substrates, respectively.

In the liquid jetting device according to still another aspect of the present disclosure, a b* value representing chromaticity of a metal in a state where the metal is precipitated by exposing the metal complex ink may be |b*|<20. According to the present aspect, the first pattern can be accurately measured by the observation device.

In the liquid jetting device according to still another aspect of the present disclosure, an a* value representing chromaticity of a metal in a state where the metal is precipitated by exposing the metal complex ink may be |a*|<20. According to the present aspect, the first pattern can be accurately measured by the observation device.

In the liquid jetting device according to still another aspect of the present disclosure, an L* value representing brightness of a metal in a state where the metal is precipitated by exposing the metal complex ink may be 40 or more. According to the present aspect, the first pattern can be accurately measured by the observation device.

In the liquid jetting device according to still another aspect of the present disclosure, a difference in an L* value representing brightness of each of a metal in a state where the metal is precipitated by exposing the metal complex ink and the substrate may be 10 or more. According to the present aspect, the first pattern can be accurately measured by the observation device.

In the liquid jetting device according to still another aspect of the present disclosure, an L* value representing brightness of the substrate may be 30 or less. According to the present aspect, the first pattern can be accurately measured by the observation device.

In the liquid jetting device according to still another aspect of the present disclosure, reflectivity of a metal in a state where the metal is precipitated by exposing the metal complex ink may be 40% or more in a visible light range. According to the present aspect, the first pattern can be accurately measured by the observation device.

In the liquid jetting device according to still another aspect of the present disclosure, the at least one processor may be configured to perform at least one of control of the liquid jetting head or presenting of information based on an evaluation result of the jetting state.

In the liquid jetting device according to still another aspect of the present disclosure, the exposure machine may be configured to generate ultraviolet light.

According to still another aspect of the present disclosure, there is provided a jetting state evaluation method comprising relatively moving a liquid jetting head and a substrate, forming a first pattern on the substrate by jetting a metal complex ink from the liquid jetting head and applying the metal complex ink to the substrate, exposing the first pattern formed on the substrate, reading the first pattern using an observation device after exposing the first pattern, and acquiring a reading result of the first pattern and evaluating a jetting state of the liquid jetting head from the reading result by at least one processor.

According to still another aspect of the present disclosure, there is provided an information processing apparatus comprising at least one processor and at least one memory that stores a command for executing the at least one processor, in which the at least one processor is configured to acquire a reading result obtained by reading a first pattern formed on a substrate by applying a metal complex ink jetted from a liquid jetting head using an observation device after exposing the first pattern and evaluate a jetting state of the liquid jetting head from the reading result.

According to still another aspect of the present disclosure, there is provided a manufacturing method of a print substrate comprising relatively moving a liquid jetting head and a print substrate, forming a first pattern on the print substrate by jetting a metal complex ink from the liquid jetting head and applying the metal complex ink to the print substrate, exposing the metal complex ink applied to the print substrate, reading the first pattern using an observation device after exposing the first pattern, acquiring a reading result of the first pattern and evaluating a jetting state of the liquid jetting head from the reading result by at least one processor, performing at least one of control of the liquid jetting head or presenting of information based on an evaluation result of the jetting state by the at least one processor, and forming a second pattern different from the first pattern on the print substrate by jetting the metal complex ink from the liquid jetting head and applying the metal complex ink to the print substrate.

According to the present disclosure, the jetting state of the liquid jetting head using the transparent metal complex ink can be evaluated.

### BRIEF DESCRIPTION OF THE DRAWINGS

FIG. 1 is a perspective view showing an example of a print substrate.

FIG. 2 is a longitudinal cross sectional view showing a three-dimensional structure of the print substrate shown in FIG. 1.

FIG. 3 is an explanatory view showing an example of a manufacturing step for manufacturing the print substrate.

FIG. 4 is a plan view schematically showing a configuration of a liquid jetting device according to embodiment 1.

FIG. 5 is a schematic side view of the liquid jetting device viewed from a right direction of FIG. 4.

FIG. 6 is a perspective view showing a configuration example of an ink jet head.

FIG. 7 is a partially enlarged view of a nozzle surface of the ink jet head.

FIG. 8 is a plan view of a nozzle surface of a head module.

FIG. 9 is a longitudinal cross sectional view showing a three-dimensional structure of an ejector.

FIG. 10 is a schematic plan view showing examples of a user pattern printing region and a test pattern printing region on the print substrate.

FIG. 11 is a view showing an example of a test pattern printed to inspect a jetting state of the ink jet head.

FIG. 12 is a view showing another example of the test pattern printed to inspect the jetting state of the ink jet head.

FIG. 13 is a functional block diagram showing an electric configuration of the liquid jetting device according to embodiment 1.

FIG. 14 is a block diagram showing a configuration example of hardware of an information processing apparatus that functions as a control device of the liquid jetting device.

FIG. 15 is a flowchart showing an example of a jetting state evaluation method performed by the liquid jetting device according to embodiment 1.

FIG. 16 is a plan view schematically showing a configuration of a liquid jetting device according to a modification example of embodiment 1.

FIG. 17 is a schematic side view of a liquid jetting device viewed from a right direction of FIG. 16.

FIG. 18 is a plan view schematically showing a configuration of a liquid jetting device according to embodiment 2.

FIG. 19 is a view showing an example of a test pattern printed to inspect a jetting state of a dispenser unit.

FIG. 20 is a view showing another example of the test pattern printed to inspect the jetting state of the dispenser unit.

FIG. 21 is a plan view schematically showing a configuration of a liquid jetting device according to embodiment 3.

FIG. 22 is a view showing an example of a test pattern printed to inspect a jetting state of a spray unit.

### DESCRIPTION OF THE PREFERRED EMBODIMENTS

Hereinafter, preferable embodiments of the present invention will be described in detail with reference to the accompanying drawings. In the present specification, the same components will be assigned with the same reference numerals, and redundant description thereof will be omitted as appropriate.

### Embodiment 1: Case of Ink Jet Type

In embodiment 1, a method of evaluating a jetting state of an ink jet head in a case where a transparent ink is used in a device that forms a pattern on a substrate using an ink jet technique will be described. Herein, a case where a pattern is formed by coating a print substrate, which is the substrate, with a metal complex ink, which is a transparent conductive ink (hereinafter, referred to as a conductive ink) will be described as an example. By coating a required site on the print substrate with the conductive ink, functions such as connecting an electric wiring line and an electromagnetic wave shield can be imparted.

The term “print substrate” is a generic term that includes a printed wiring board (PWB) in a state before an integrated circuit (IC) or an electric component such as a resistor is attached and a printed circuit board (PCB) in a state where an electric component is attached to the printed wiring board. The electric component is called an electronic component in some cases. The printed wiring board is called a wiring board in some cases, and the printed circuit board is called an electric circuit mounted substrate in some cases. The print substrate may be a rigid substrate, may be a flexible substrate, or may be an aluminum substrate. The print substrate may be a printed circuit board in the middle of manufacturing before being completed as a circuit or may be a large substrate before being cut into individual pieces (individual substrate).

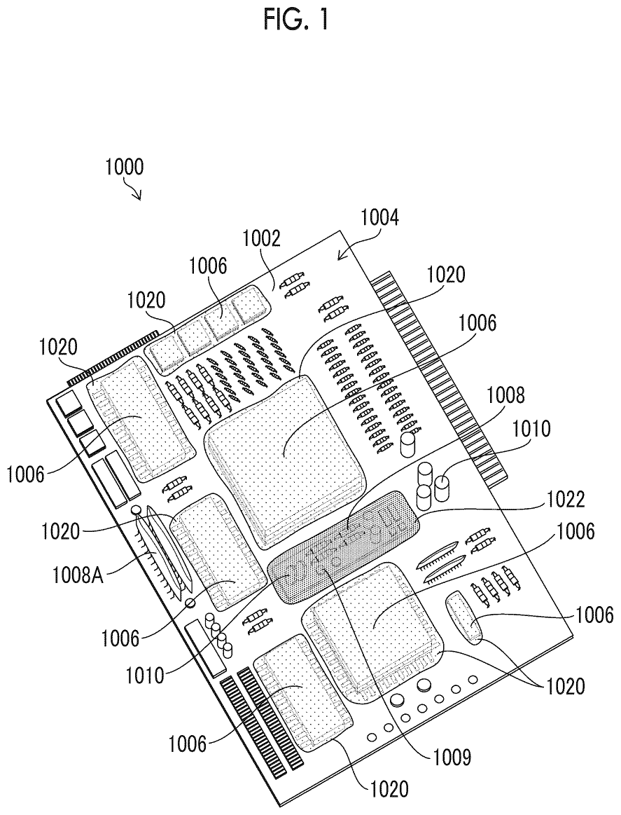

FIG. 1 is a perspective view showing an example of the print substrate. A print substrate 1000 shown in FIG. 1 is an electric circuit mounted substrate obtained by mounting electric components such as an IC 1006, a resistor 1008, and a capacitor 1010 on a component mounting surface 1004 of a wiring board 1002. In the print substrate 1000, a conductive pattern 1020 is formed with respect to the IC 1006, and an insulating coating 1022 is formed with respect to the resistor 1008 and the capacitor 1010. In addition, in the print substrate 1000, the insulating coating 1022 is formed with respect to an electrode 1009 that is exposed without the electric components of the wiring board 1002 being mounted. Although FIG. 1 shows an example in which one surface of the wiring board 1002 is the component mounting surface 1004, both surfaces of the wiring board 1002 may be component mounting surfaces.

The IC 1006 is an electric component in which a semiconductor integrated circuit is sealed with a package such as a resin. In the IC 1006, an electrode is exposed to the outside of the package. The resistor 1008 includes an electric resistance element. In addition, the resistor 1008 includes a resistance array 1008A in which a plurality of integrated electric resistance elements are sealed with a package made of a resin or the like. The capacitor 1010 includes various types of capacitors such as an electrolytic capacitor and a ceramic capacitor.

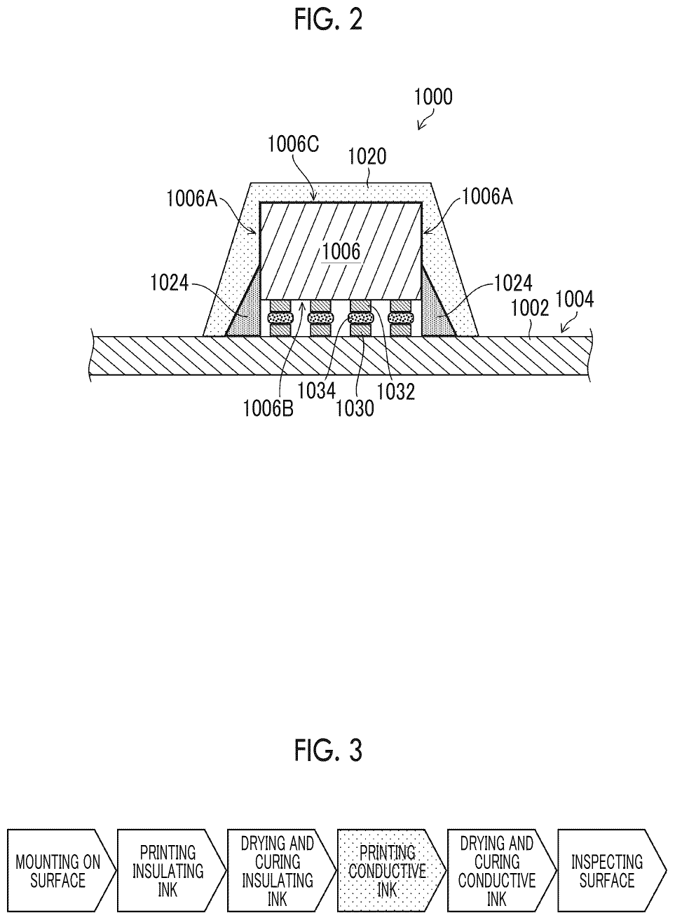

In a region where the IC 1006, among electronic components mounted on the wiring board 1002, is disposed, an insulating pattern 1024 (see FIG. 2) is formed using an insulating ink, and the conductive pattern 1020 is formed using a conductive ink with respect to at least a part of the insulating pattern 1024. In FIG. 1, the insulating pattern 1024 is not shown.

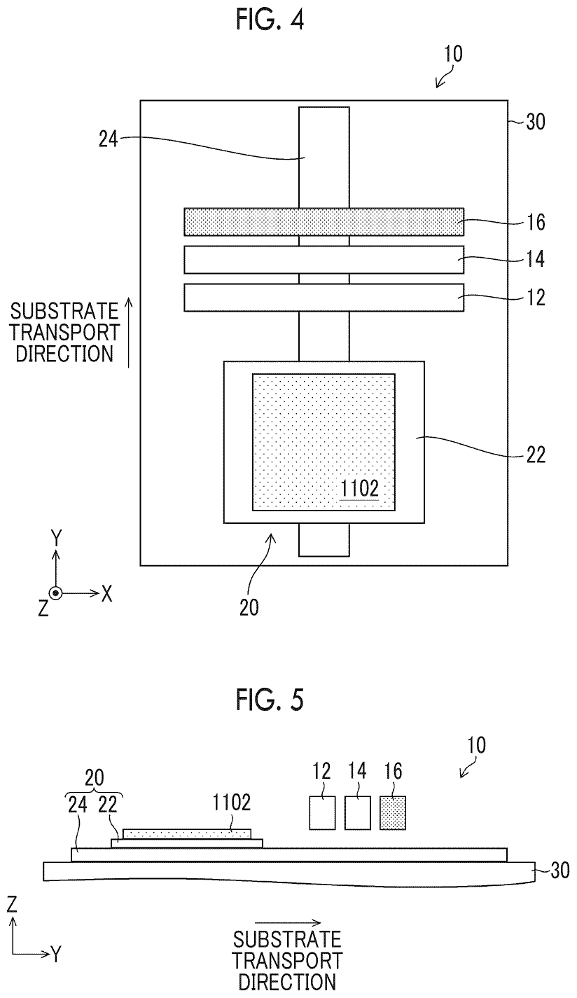

The conductive pattern 1020 is formed by disposing a conductive ink in a region on the print substrate 1000 where the conductive pattern 1020 is to be formed by a liquid jetting head such as an ink jet head 12 (see FIG. 4) and then drying and curing a continuous body of ink dots of the conductive ink.

Similarly, the insulating coating 1022 and the insulating pattern 1024 are formed by disposing insulating inks on a region where the insulating coating 1022 and the insulating pattern 1024 are to be formed on the print substrate 1000 by a liquid jetting head for an insulating ink (not shown) and drying and curing a continuous body of the insulating inks thereafter.

The conductive pattern 1020 functions as an electromagnetic wave shield aimed at suppressing electromagnetic waves received by the IC 1006 and suppressing electromagnetic waves released from the IC 1006. The insulating pattern 1024 functions as an insulating member that ensures electric insulation between the conductive pattern 1020 and the IC 1006, an adhesive member that ensures adhesiveness between the conductive pattern 1020 and the IC 1006, a member that ensures flatness of a base of the conductive pattern 1020, and the like.

In addition, in at least a part of a component region in the wiring board 1002 where an electric component that does not require an electromagnetic wave shield, the conductive pattern 1020 is not formed, and the part of the component region is coated with the insulating coating 1022. Examples of the electrical component that does not require the electromagnetic wave shield include a diode, a coil, a transformer, and a switch, in addition to the resistor 1008 and the capacitor 1010.

In addition, an electrode region of the component mounting surface 1004 of the wiring board 1002 where the electrode 1009 is disposed on the surface is coated using the insulating coating 1022. The insulating coating 1022 suppresses a short circuit of an electric circuit that occurs as a finely granulated conductive ink is attached to the resistor 1008 or the like in a case where the conductive pattern 1020 is formed.

FIG. 2 is a sectional view showing a three-dimensional structure of the print substrate 1000 shown in FIG. 1. FIG. 2 schematically shows a cross section of a state where the insulating pattern 1024 and the conductive pattern 1020 are formed for any IC 1006 on the print substrate 1000.

A substrate-side electrode 1030 formed on the component mounting surface 1004 of the wiring board 1002 and an element-side electrode 1032 of the IC 1006 are electrically connected to each other via a solder bump 1034.

The insulating pattern 1024 is formed on the periphery of the IC 1006 surrounding four side surfaces 1006A of the IC 1006 and is on a wiring board 1002 side of a back surface 1006B on which the element-side electrode 1032 of the IC 1006 is formed. The insulating pattern 1024 may be formed at a position in contact with the side surfaces 1006A of the IC 1006. In addition, although not shown, the insulating pattern 1024 may be formed between the back surface 1006B of the IC 1006 and the component mounting surface 1004 of the wiring board 1002.

The conductive pattern 1020 is formed to overlap at least a part of the insulating pattern 1024. FIG. 2 shows an example in which the conductive pattern 1020 overlaps an entire surface of the insulating pattern 1024.

In addition, the conductive pattern 1020 may be formed in a region that covers the side surfaces 1006A of the IC 1006 and an upper surface 1006C of the IC 1006. The insulating pattern 1024 that is the base of the conductive pattern 1020 may be formed on the side surfaces 1006A of the IC 1006 and the upper surface of the IC 1006.

Although not shown, in a case where electrodes protruding from the side surfaces 1006A of the IC 1006 to an outer side of the IC 1006 are included, the insulating pattern 1024 is formed in a region where at least all electrodes are coated.

Although FIG. 2 shows the print substrate 1000 where the conductive pattern 1020 is exposed, a protective film may be formed to overlap the conductive pattern 1020. The protective film may have insulating properties.

### <<Outline of Manufacturing Method of Print Substrate>>

FIG. 3 is an explanatory view showing an example of a manufacturing step for manufacturing the print substrate 1000. The manufacturing step of the print substrate 1000 includes a surface mounting step, an insulating ink printing step, an insulating ink drying and curing step, a conductive ink printing step, a conductive ink drying and curing step, and a surface inspection step. In the example of FIG. 3, an insulating ink is printed before the conductive ink printing step, and a process of drying and curing the insulating ink is also included. The term “printing” includes a meaning of forming a pattern using an ink. In addition, the term “printing” is also used as a term meaning application (coating) of the ink.

The surface mounting step is a step of mounting an electric component such as the IC 1006, the resistor 1008, and the capacitor 1010 on the component mounting surface 1004 of the wiring board 1002. The surface mounting step may include a step in which a paste coating device (not shown) coats the wiring board 1002 with a solder paste, a mounting step in which a surface mounting device (not shown) disposes an electric component on the solder paste of the wiring board 1002, and a reflow step in which a reflow furnace (not shown) melts and cools the solder paste of the wiring board 1002 where the electric component is disposed.

The insulating ink printing step is a step of coating with an insulating ink in order to improve adhesiveness of a site or a conductive ink that has a risk of short-circuiting due to attachment of the conductive ink before printing the conductive pattern 1020 with the conductive ink. Although an ultraviolet ray curing ink (UV ink) that is cured through irradiation of ultraviolet rays is generally used as the insulating ink, the insulating ink is not necessarily an ultraviolet ray curable-type ink insofar as insulating properties are obtained after curing.

The insulating ink drying and curing step is a step of drying and curing an insulating ink. In a case where the insulating ink is an ultraviolet ray curable-type ink, a drying and curing device includes an ultraviolet irradiation device such as an ultraviolet ray emitting diode and an ultraviolet laser diode. The drying and curing device may include a heater.

The conductive ink printing step is a step of printing the conductive pattern 1020 using a conductive ink. In the present embodiment, a metal complex ink is used as the conductive ink. Herein, the metal complex ink means, for example, an ink obtained by dissolving a metal such as silver and aluminum in a solvent. The metal complex ink used in the present embodiment 1 substantially does not contain a polymerization initiator put into a normal UV ink (for example, a UV ink used in JP2011-083916A).

A liquid jetting device that jets a conductive ink and a liquid jetting device that jets an insulating ink may be configured as separate devices or may be configured as one liquid jetting device comprising a liquid jetting head that jets the conductive ink and a liquid jetting head that jets the insulating ink.

The conductive ink drying and curing step is a step of drying and curing a printed conductive ink. The drying and curing device used in the conductive ink drying and curing step includes the ultraviolet irradiation device.

The surface inspection step is, for example, a step of inspecting an appearance (surface) of the print substrate 1000 using an appearance inspecting device or the like. Although not shown in FIG. 3, after the surface inspection step, further subsequent steps may be included, such as a step of cutting into individual pieces.

### <<Need to Evaluate Jetting State of Liquid Jetting Head>>

In the manufacturing step of the print substrate 1000 in a factory, while printing is repeated on the print substrate 1000 using the liquid jetting head such as the ink jet head, the jetting state of the liquid jetting head may gradually deteriorate. In a case where no measures are taken against deterioration of the jetting state, eventually, electric connection of the electric wiring line cannot be ensured or coating is insufficient so that a function of the electromagnetic wave shield is insufficient in some cases.

In order to avoid such a situation, in the present embodiment 1, a method of punching a test pattern for inspecting the jetting state of the ink jet head in the print substrate in a case of using a metal complex ink which is a transparent conductive ink, inspecting printing results of the test pattern using an observation device, and feeding the inspection results back to an ink jet printing unit is disclosed. Formation of the test pattern using the conductive ink, reading of the test pattern, and evaluation of the jetting state based on the reading results are executed in a case of starting the conductive ink printing step and/or during a period of the conductive ink printing step.

### <<Configuration Example of Liquid Jetting Device Used in Manufacturing of Print Substrate>>

FIG. 4 is a plan view schematically showing a configuration of a liquid jetting device 10 according to embodiment 1. FIG. 5 is a side view of the liquid jetting device 10 viewed from a right direction of FIG. 4.

The liquid jetting device 10 is an ink jet printing device that coats a print substrate 1102 with a conductive ink. The print substrate 1102 herein is a large substrate before being cut into individual pieces, and regions corresponding to a plurality of individual substrates can be imposed on the print substrate 1102. The liquid jetting device 10 comprises the ink jet head 12, a UV exposure machine 14, a scanner 16, and a transport device 20 that transports the print substrate 1102. The ink jet head 12, the UV exposure machine 14, and the scanner 16 are supported by a support member (not shown) and are fixed to a base plate 30 via the support member. The base plate 30 may be, for example, a flat plate.

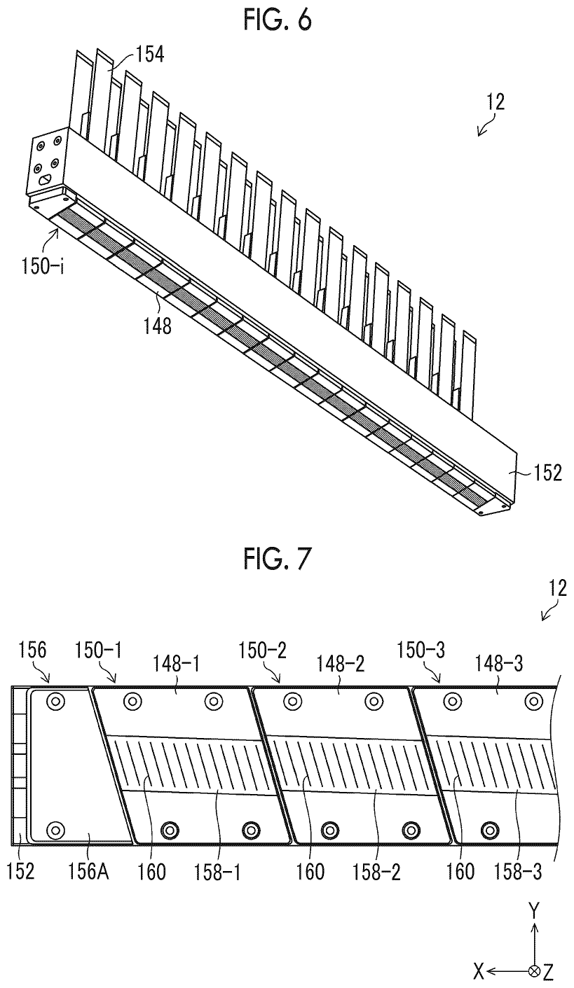

The ink jet head 12 is a line type liquid jetting head that has a plurality of nozzles which jet a metal complex ink which is a transparent conductive ink. The ink jet head 12 has a nozzle line that can perform printing of an entire print region of the print substrate 1102 in a defined print resolution with one time of scanning in a width direction of the print substrate 1102 (an X-direction in FIG. 4). A configuration example of the ink jet head 12 will be described later (FIGS. 6 to 8).

The transport device 20 includes a transport stage 22 that supports the print substrate 1102 and a moving mechanism 24 that moves the transport stage 22. The transport device 20 is disposed on an upper surface of the base plate 30. The transport stage 22 comprises a fixing mechanism that fixes the print substrate 1102. The fixing mechanism may be in a form of a clamp or the like that mechanically fixes the print substrate 1102 or may be in a form of adsorbing the print substrate 1102 by applying a negative pressure. The print substrate 1102 is fixed to the transport stage 22 in a state where the component mounting surface 1004 is directed in a +Z-direction. The transport stage 22 may comprise an adjustment mechanism that adjusts a distance (a distance in a Z-direction) between the ink jet head 12 and the print substrate 1102. In addition, the transport stage 22 may be configured to adjust a position in the X-direction.

The moving mechanism 24 is a mechanism that moves the transport stage 22 along a Y-direction. The Y-direction is a direction perpendicular to the X-direction and the Z-direction. In the moving mechanism 24, for example, a ball screw drive mechanism, a belt drive mechanism, and the like are coupled to a rotation shaft of a motor. The moving mechanism 24 may comprise a linear motor. The transport device 20 is an example of a relative moving mechanism that relatively moves the ink jet head 12 and the print substrate 1102.

The UV exposure machine 14 is, for example, a line type UV-light emitting diode (LED) and has a UV irradiation region where the entire region of a drawing width of the ink jet head 12 in the X-direction can be exposed. The UV exposure machine 14 is an example of an exposure machine. A configuration of the UV exposure machine 14 is not limited to the example, and the UV exposure machine 14 may be an ultraviolet irradiation device using a micro electro mechanical system (MEMS) mirror or a polygon mirror.

A one-direction printing device configuration where printing is performed in a case of transporting the print substrate 1102 in a direction from down to up of FIG. 4 (+Y-direction) is given as an example of the liquid jetting device 10 of the present embodiment 1, and the UV exposure machine 14 is disposed on a downstream side of the ink jet head 12 with respect to a transport direction of the print substrate 1102 in a case of printing. Such a one-direction printing device configuration is not limited, and for example, UV exposure machines may be disposed on both sides of the ink jet head 12 in a case of a device configuration corresponding to uni-directional printing in which printing is possible also during transporting of the print substrate 1102 from up to down of FIG. 4.

After ink jetting by the ink jet head 12, exposure is performed using the UV exposure machine 14. Accordingly, a metal in an ink is precipitated, and printing results can be read by the scanner 16. As a result, by analyzing the read image, the jetting state of the ink jet head 12 can be evaluated. The term “precipitate” in the present disclosure refers to reduction of a metal complex or a metal salt contained in the ink, but is not limited to the phenomenon.

The scanner 16 is, for example, a line scanner. The scanner 16 includes an imaging device, a lens, an illumination light source, and a signal processing circuit that generates digital image data by processing a signal obtained from the imaging device. For example, a color charge-coupled device (CCD) linear image sensor is used as the imaging device. The color CCD linear image sensor is an image sensor in which light-receiving elements comprising color filters of respective colors including red (R), green (G), and blue (B) are linearly arrayed. A color complementary metal oxide semiconductor (CMOS) linear image sensor can also be used instead of the color CCD linear image sensor. The scanner 16 reads a test pattern while the transport device 20 transports the print substrate 1102 and acquires a read image.

The scanner 16 is an example of the observation device. Without being limited to the scanner 16, a test pattern on the print substrate 1102 may be imaged using a camera. In addition, without being limited to the scanner 16 mounted on the liquid jetting device 10, the test pattern on the print substrate 1102 may be imaged using a scanner provided outside the liquid jetting device 10 or the observation device such as a camera. The observation device may be rephrased as an imaging apparatus, and reading may be rephrased as “imaging”.

### <<Configuration Example of Ink Jet Head 12>>

FIG. 6 is a perspective view showing a configuration example of the ink jet head 12. The ink jet head 12 has a structure in which a plurality of head modules 150-i are joined to each other along a longitudinal direction. i is an integer from 1 to n and represents a number of a head module. n is the number of head modules constituting the ink jet head 12.

The plurality of head modules 150-i are attached to a support frame 152 and are integrated in a bar shape. Each of the head modules 150-i comprises a flexible substrate 154 for electric connection.

FIG. 7 is a partially enlarged view of a nozzle surface 148 of the ink jet head 12. A nozzle surface 148-i of the head module 150-i has a parallelogram shape. Dummy plates 156 are attached to both ends of the support frame 152 in the longitudinal direction. The nozzle surface 148 of the ink jet head 12 has an oblong shape as a whole together with surfaces 156A of the dummy plates 156.

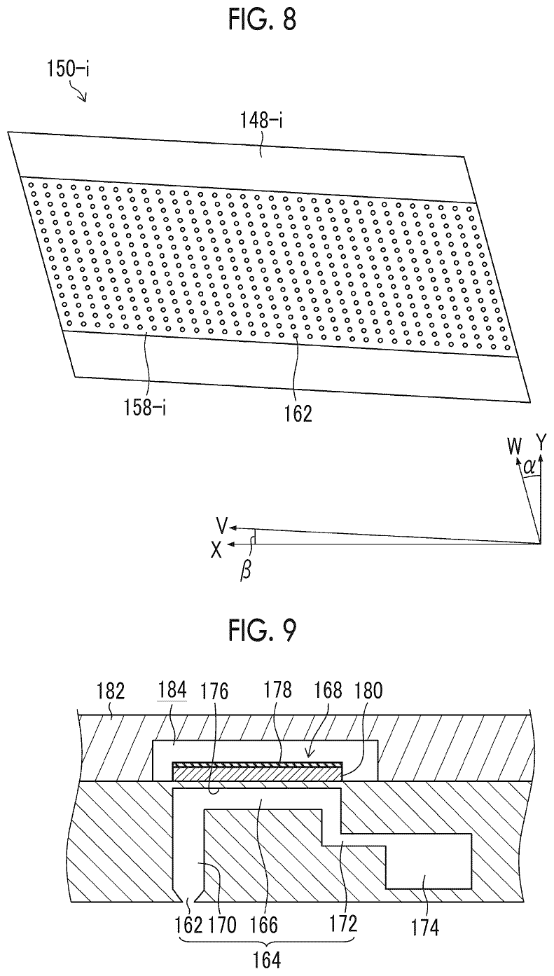

A belt-shaped nozzle disposition portion 158-i is included at a central portion of the nozzle surface 148-i of the head module 150-i. The nozzle disposition portion 158-i functions as the substantial nozzle surface 148-i. A nozzle 162 (see FIG. 8) which is an ink outlet is included in the nozzle disposition portion 158-i. In FIG. 7, the nozzle 162 is not shown individually, but nozzle lines 160 composed of a plurality of nozzles are shown.

FIG. 8 is a plan view of the nozzle surface 148-i of the head module 150-i. A plurality of nozzles 162 are two-dimensionally arrayed in the nozzle surface 148-i of the head module 150-i.

The head module 150-i has a parallelogram plan view shape having end surfaces on a long side along a V-direction having an inclination of an angle β with respect to the X-direction and end surfaces on a short side along a W-direction having an inclination of an angle α with respect to the Y-direction.

In the head module 150-i, the plurality of nozzles 162 are disposed in a matrix in a row direction along the V-direction and a column direction along the W-direction. In a case of the ink jet head 12, a projected nozzle line in which the respective nozzles 162 are projected to be arranged along the X-direction can be considered to be equivalent to one nozzle line in which the respective nozzles 162 are arranged at substantially equal intervals at a nozzle density that achieves the maximum recording resolution for the X-direction. In consideration of the projected nozzle line, each nozzle 162 can be assigned with a nozzle number representing a nozzle position in order of projected nozzles arranged along the X-direction.

The term “substantially equal intervals” means that dropping points that can be printed by the liquid jetting device 10 are at substantially equal intervals. For example, a case where the intervals are slightly different in consideration of at least any one of a manufacturing error or movement of liquid droplets on the print substrate 1102 due to landing interference is also included in the concept of the equal intervals.

The arrangement form of the nozzle 162 of the ink jet head 12 is not limited, and various nozzle array forms can be adopted. For example, a single row linear array, a V-shaped array, a W-shaped zigzag array with a V-shaped array as a repeating unit may be adopted.

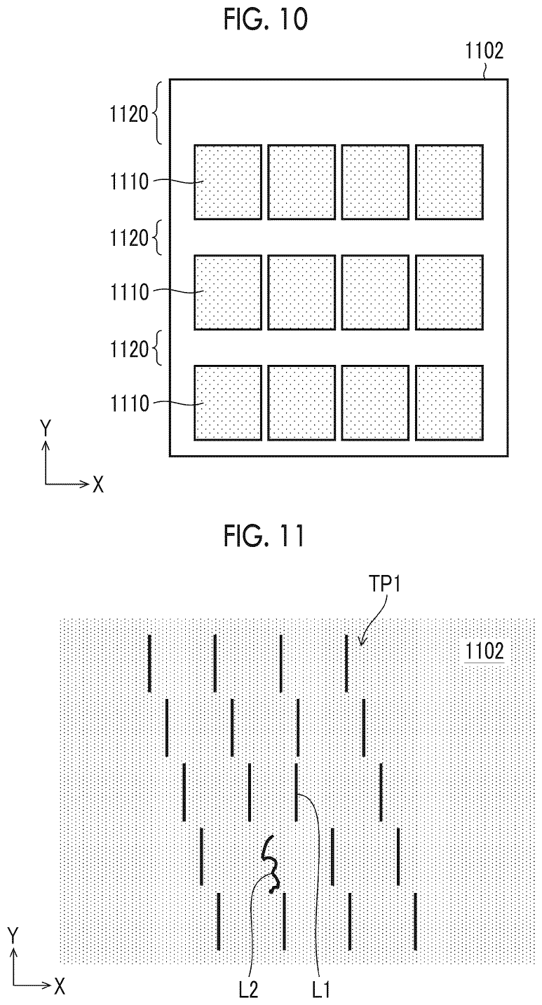

FIG. 9 is a longitudinal cross sectional view showing a three-dimensional structure of an ejector 164. The ejector 164 comprises the nozzle 162, a pressure chamber 166 that communicates with the nozzle 162, and a piezoelectric element 168. The nozzle 162 communicates with the pressure chamber 166 via a nozzle flow passage 170. The pressure chamber 166 communicates with a supply-side common branch flow passage 174 via an individual supply passage 172.

A vibration plate 176 constituting a top surface of the pressure chamber 166 comprises a conductive layer (not shown) that functions as a common electrode corresponding to a lower electrode of the piezoelectric element 168. The pressure chamber 166, wall portions of the other flow passage portions, and the vibration plate 176 can be made of silicon.

A material for the vibration plate 176 is not limited to silicon, and the vibration plate 176 may be formed of a non-conductive material such as a resin. The vibration plate 176 itself may be formed of a metal material such as stainless steel and be used as a vibration plate that also serves as the common electrode.

A piezoelectric unimorph actuator is composed of a structure in which the piezoelectric element 168 is laminated with respect to the vibration plate 176. A drive voltage is applied to an individual electrode 178 that is an upper electrode of the piezoelectric element 168 to deform a piezoelectric body 180, and the vibration plate 176 is bent to change the volume of the pressure chamber 166. A pressure change caused by the change in the volume of the pressure chamber 166 acts on an ink so that the ink is jetted from the nozzle 162.

In a case where the piezoelectric element 168 is restored to an original state after jetting of an ink, the pressure chamber 166 is filled with a new ink from the supply-side common branch flow passage 174 through the individual supply passage 172. An operation of filling the pressure chamber 166 with the ink is referred to as refilling.

A plan-view shape of the pressure chamber 166 is not particularly limited and may be a quadrangular shape, other polygonal shapes, a circular shape, an elliptical shape, or the like. A cover plate 182 is provided above the individual electrode 178. The cover plate 182 is a member that holds a movable space 184 of the piezoelectric element 168 and seals a periphery of the piezoelectric element 168.

A supply-side ink chamber (not shown) and a collection-side ink chamber (not shown) are formed above the cover plate 182. The supply-side ink chamber is coupled to a supply-side common main flow passage (not shown) via a communication path (not shown). The collection-side ink chamber is coupled to a collection-side common main flow passage (not shown) via the communication path (not shown).

Each nozzle 162 of the ink jet head 12 can jet each of inks having a plurality of droplet amounts (liquid droplet sizes) and can dispose ink dots having a plurality of sizes on the component mounting surface 1004 of the print substrate 1102. For example, the ink jet head 12 may be capable of jetting three types of droplet amounts including small droplets, medium droplets, and large droplets from each nozzle 162. A form and a head module number of the head module 150-i constituting the ink jet head 12 are not limited to examples of FIGS. 6 to 9.

### <<Jetting Type of Ink Jet Head>>

In general, an ejector of an ink jet head is composed of a nozzle that jets an ink, a pressure chamber that communicates with the nozzle, and a jetting energy generating element that applies jetting energy to a liquid in the pressure chamber. Regarding a jetting type of jetting liquid droplets from the nozzle of the ejector, a unit that generates jetting energy is not limited to a piezoelectric element, and various jetting energy generating elements, such as a heat generating element and an electrostatic actuator, can be applied. For example, a type of jetting liquid droplets by using a pressure during film boiling caused by heating of the liquid by the heat generating element can be adopted. Depending on the jetting type of the ink jet head, a jetting energy generating element corresponding thereto is provided in a flow path structure.

### <<Example of Test Pattern Printing Region on Print Substrate>>

FIG. 10 schematically shows examples of a user pattern printing region 1110 and a test pattern printing region 1120 on the print substrate 1102. The print substrate 1102 can have various sizes. The size of the print substrate 1102 may be, for example, 250 mm×250 mm or 500 mm×500 mm.

The print substrate 1102 includes a plurality of user pattern printing regions 1110 and a plurality of test pattern printing regions 1120. Each user pattern printing region 1110 is a region of an individual substrate that is cut as an individual piece (individual substrate) of a circuit board and that is separated individually in a subsequent step after printing. The print substrate 1000 described with reference to FIG. 1 corresponds to the individual substrate corresponding to one user pattern printing region 1110 shown in FIG. 10.

A pattern printed in the user pattern printing region 1110 is referred to as a user pattern. The user pattern is a pattern required by a user, and a desired pattern for printing is designated by the user. The user pattern may be any pattern that realizes a performance of a circuit board required by the user. Data for printing the user pattern is generated according to design of the circuit board that is a manufacturing target.

FIG. 10 shows an example in which 12 user pattern printing regions 1110 are disposed (imposed) on one print substrate 1102 in an array form of 3 rows and 4 columns. The test pattern printing region 1120 may be, for example, a space between rows of the user pattern printing regions 1110 and/or a region near an end part of the print substrate 1102 in the Y-direction. The shapes, the number, and the array forms of the user pattern printing regions 1110 and the number and the disposition forms of the test pattern printing regions 1120 are not limited to the example of FIG. 10, and there can be various forms.

A test pattern for nozzle inspection for inspecting a jetting state of each nozzle of the ink jet head 12 is printed in the test pattern printing region 1120. The test pattern is printed based on test pattern printing data determined in advance. The test pattern printed in the test pattern printing region 1120 is an example of a “first pattern” in the present disclosure, and a user pattern printed in the user pattern printing region 1110 is an example of a “second pattern” in the present disclosure.

### <<Example 1 of Test Pattern>>

FIG. 11 is example 1 of a test pattern printed on the print substrate 1102. The liquid jetting device 10 prints, for example, a test pattern TP1 shown in FIG. 11 in the test pattern printing region 1120 shown in FIG. 10 and exposes and colors the test pattern TP1 with the UV exposure machine 14.

FIG. 11 shows a part of the test pattern TP1 for convenience of showing. The test pattern TP1 is a pattern for inspecting the jetting state of each of the nozzles of the ink jet head 12 and may be, for example, a line pattern in which lines independently recorded by each of the nozzles in the line type ink jet head 12 are arranged. The test pattern TP1 may be a line pattern in which lines independent for respective nozzles, which are formed as the respective nozzles perform a continuous jetting operation through so-called jetting control of “1 on N off” performed on substantial nozzle lines in which the nozzles of the ink jet head 12 are arranged in the X-direction, are arranged. FIG. 11 shows an example of N=4 (a line pattern of 1 on 4 off).

All the nozzles included in the ink jet head 12 continuously perform jetting independently of each other to draw a line for each nozzle, a pattern is colored through UV exposure, and the printing results are observed so that jetting states of all the nozzles can be evaluated.

By observing the test pattern TP1 shown in FIG. 11 with the scanner 16, a bent jetting nozzle, an unstable jetting nozzle, and the like can be found. The bent jetting nozzle can be determined by a relative positional relationship with lines, dots, or the like printed by other nozzles.

In the example of the test pattern TP1 shown in FIG. 11, there are a line L1 of which a printing position (landing position) in the X-direction is deviated and a curved line L2 that does not extend parallel to the Y-direction. The line L1 represents a dot row printed by nozzles (bent jetting nozzles) in which bent jetting has occurred. The curved line L2 represents a dot row printed by nozzles in which jetting is unstable (unstable jetting nozzles). Nozzles of which jetting states are determined to be abnormal, such as the bent jetting nozzles, the unstable jetting nozzles, and non-jetting nozzles, are referred to as “abnormal jetting nozzles”.

By detecting the lines L1 and L2 using the scanner 16, a bent jetting nozzle, an unstable jetting nozzle, and the like can be determined to have abnormal jetting states.

### <<Use Example of Evaluation Results of Jetting State>>

As a result of observation using the scanner 16, information of a nozzle of which a jetting state is determined to be abnormal is transmitted to a printing unit. Herein, the term “printing unit” refers to an ink jet printing unit that includes the ink jet head 12 and a control unit which controls a printing operation by the ink jet head 12. The control unit stops jetting of an ink from a nozzle of which a jetting state is determined to be abnormal. To compensate dropping carried out by an abnormal jetting nozzle which has stopped jetting, the control unit can execute a correction process of controlling dropping from nozzles in the vicinity thereof.

In addition, in a case where the number of abnormal jetting nozzles of the ink jet head 12 is determined to be larger than an allowable value, for example, a case where 10% or more of all the nozzles are “abnormal jetting nozzles”, the control unit can also instruct an operator to stop ink coating on the print substrate 1102 by the ink jet head 12.

The allowable value, such as 10% of all the nozzles, is an example of a reference value (threshold value) determined in advance. Alternatively, in a case where the number of abnormal jetting nozzles is determined to be larger than the allowable value, a case where a certain number or more of abnormal jetting nozzles having consecutive nozzle numbers are determined to be generated, or the like, the control unit can also forcibly stop ink coating by the ink jet head 12. Alternatively, in a case where the number of abnormal jetting nozzles is determined to be larger than the allowable value, the control unit can also instruct the operator to perform head cleaning on the ink jet head 12 or automatically execute head cleaning.

Then, in a case where a jetting state is determined to be not restored even after head cleaning is performed, the control unit can also instruct the operator to replace the ink jet head 12.

### <<Example 2 of Test Pattern>>

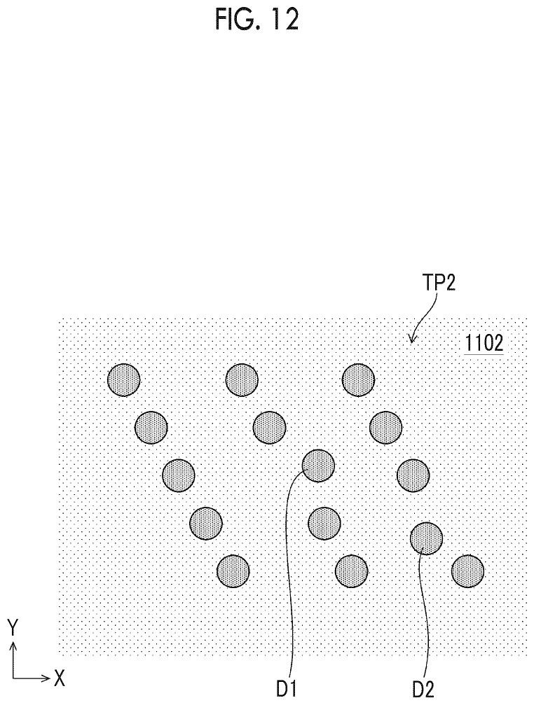

FIG. 12 is example 2 of a test pattern printed on the print substrate 1102. A pattern for inspecting a jetting state of a nozzle may be a dot pattern in which isolated dots are printed by each nozzle. A test pattern TP2 shown in FIG. 12 is a dot pattern of “1 on 4 off”. Each dot is formed through dropping from different nozzles.

In the test pattern TP2 shown in FIG. 12, jetting deviation in a relative moving direction (herein, the Y-direction) of the print substrate 1102 and the ink jet head 12 is also easily evaluated. Also in a line pattern such as the test pattern TP1 shown in FIG. 7, jetting deviation in the relative moving direction can be measured. The jetting deviation can be determined by deviation from a relative position with other dots or a center position of a captured image.

In the example of the test pattern TP2 shown in FIG. 12, there are a dot D1 and a dot D2 of which positions in the X-direction and the Y-direction are deviated from other dots. The nozzles 162 that have printed the dot D1 and the dot D2 have performed bent jetting or unstable jetting. By detecting the dots using the scanner 16, a bent jetting nozzle and an unstable jetting nozzle can be determined to have abnormal jetting states. The liquid jetting device 10 can control the nozzles determined to have abnormal jetting states in the same manner as a case described in the test pattern TP1, such as stopping jetting, giving notification to the operator to instruct necessary work such as head cleaning, or the like.

Each of the test pattern TP1 shown in FIG. 11 and the test pattern TP2 shown in FIG. 12 is an example of the first pattern. A pattern printed using a conductive ink in the conductive pattern 1020 shown in FIG. 1 and the user pattern printing region 1110 described with reference to FIG. 10 are an example of the second pattern.

<<Position where Test Pattern is Formed on Print Substrate>>

As described with reference to FIG. 10, in a case where both a user pattern and a test pattern are formed on one print substrate 1102, it is desirable to print the test pattern in a substrate region finally excised (cut down) from the print substrate 1102. For example, the test pattern printing region 1120 may be a space between an individual substrate allocated to the print substrate 1102 and an individual substrate or a region of a frame of an edge part for substrate handling. The test pattern printing region 1120 shown in FIG. 10 is an example of a finally excised portion.

As described above, by printing a test pattern in a finally excised substrate region, there is no need to separately ensure an area necessary for printing the test pattern in the print substrate 1102. Thus, a user pattern printing region can be ensured, and an increase in a material loss of the print substrate 1102 can be suppressed.

In addition, in a case where printing is performed on the print substrate 1102 where the user pattern printing region 1110 and the test pattern printing region 1120 shown in FIG. 10 are mixed, it is desirable to print a test pattern before printing a user pattern during relative movement between the print substrate 1102 and the ink jet head 12. That is, it is desirable to perform an operation in which through relative movement between the print substrate 1102 and the ink jet head 12 by the transport device 20, the test pattern printing region 1120 arrives first with respect to the ink jet head 12, the user pattern printing region 1110 arrives after printing the test pattern in the test pattern printing region 1120, and the user pattern is printed in the user pattern printing region 1110. In a case of FIG. 10, it is preferable that printing (formation of a pattern) proceeds from up to down of the print substrate 1102, that is, the print substrate 1102 is transported in an upward direction of FIG. 10 (+Y-direction) to jet a conductive ink from the ink jet head 12 (see FIG. 4).

By doing so, since an ink in a nozzle is brought into a fresh state through test pattern printing, the same effects as dummy jetting (preliminary jetting) are obtained, and a probability that user pattern printing is well performed increases. In particular, since a metal complex ink is more likely to thicken compared to a normally used ink, effects of dummy jetting are further improved.

In addition, it is evident that it is not necessary to form a user pattern and a test pattern on the same (one) print substrate, and a test pattern substrate can also be prepared. For example, by using the test pattern substrate after head cleaning or after major maintenance such as head replacement is performed, measurement with a high degree of freedom can be performed, such as measurement accuracy can be increased by extending each line of a line pattern such as the test pattern TP1 and the number of nozzles that can be evaluated all at once can be increased. The test pattern substrate is an example of a “first substrate” in the present disclosure, and a user pattern substrate is an example of a “second substrate” in the present disclosure.

### <<Exposure Amount by UV Exposure Machine 14>>

While it is necessary for an exposure amount of a test pattern by the UV exposure machine 14 to satisfy conditions of UV irradiation energy sufficient to color the test pattern observably, it is desirable to avoid an increase in irradiation intensity of UV light more than it needs. This is because in order to perform exposure with high UV irradiation energy, it is necessary to increase the capacity of the UV exposure machine 14, leading to an increase in costs of the device. In addition, there is a possibility that leakage light of UV generated by the UV exposure machine 14 reaches a nozzle unit of the ink jet head 12, and this is because a risk that leads to a defect in jetting increases by thickening an ink in the nozzle 162 with leakage light.

Thus, it is desirable that the exposure amount of the test pattern by the UV exposure machine 14 is less than 500 mJ/cm² which is a level at which a metal complex ink is observable with the scanner 16. As a matter of fact, there is no problem in reading with the scanner 16 in a case where the exposure amount is 300 mJ/cm² or less. Accordingly, it is further desirable that the exposure amount of the test pattern by the UV exposure machine 14 is 300 mJ/cm² or less.

In addition, the exposure amount of the test pattern by the UV exposure machine 14 is preferably larger than the exposure amount of the user pattern by the UV exposure machine 14. Exposure to the user pattern is sufficient in any case insofar as an ink is cured to a minimum extent that an increase in fluidity of the ink is suppressed such that the ink after printing is not wet and spreads indefinitely. Even in a case where the user pattern is not completely dried and cured in the liquid jetting device 10, after being taken out from the liquid jetting device 10, the print substrate 1102 on which the user pattern is printed can also be further dried and cured using a separate UV light source (not shown) and can also be dried and cured by being heated using an oven (not shown). In such a case, an advantage that a degree of freedom of the process is increased by performing processing of drying and curing with separate devices that perform the process.

The exposure amount of the user pattern is desirably an exposure amount that is a minimum exposure amount at which the spread of an ink does not cause a problem, for example, is desirably an exposure amount of 30 mJ/cm² or more and 100 mJ/cm² or less at which the spread of the ink can be suppressed. The exposure amount of the user pattern may be, for example, ⅕ of the exposure amount of the test pattern or less.

<<Color in Case where Metal Complex Ink is Cured>>

In a case where a metal complex ink used in the present embodiment 1 is appropriately cured, a b* value representing chromaticity at which the metal complex ink is in an opaque state is |b*|<20. As a result, in a substrate such as the print substrate 1102, since the substrate itself is colored normally, an ink color difference is likely to appear, and measurement accuracy of the scanner 16 increases.

The same applies to an a* value. In a case where a metal complex ink is appropriately cured, the a* value in a state where the metal complex ink is opaque is |a*|<20. As a result, since a printing substrate such as a print substrate is colored normally, an ink color difference is likely to appear, and measurement accuracy of the scanner 16 increases.

Regarding an L*value representing brightness, in a case where a metal complex ink is appropriately cured, the L*value is 40 or more. As a result, an ink color difference is likely to appear, and the measurement accuracy of the scanner 16 increases. In a case where the difference in the L*value from that of the substrate is 10 or more, the scanner 16 can also perform measurement with sufficient accuracy. Each value of L*, a*, and b* is a value of each component in a CIE L*a*b* color system defined by Commission Internationale de l'Eclairage (CIE).

By performing color measurement using a colorimeter after a metal complex ink is subjected to UV exposure, L*a*b* values of a metal precipitated with UV exposure can be acquired.

<<Reflectivity of Case where Metal Complex Ink is Cured>>

In a case where a metal complex ink is appropriately cured, reflectivity is 40% or more in a visible light range (wavelength of 400 nm to 800 nm). As a result, a difference in reflectivity from a substrate, which is a base, is generated, and the measurement accuracy of the scanner 16 increases. An L*value representing the brightness of the wiring board 1002 as a substrate which is a base may be, for example, 30 or less.

### <<Metal Complex Ink>>

A metal complex ink is, for example, an ink composition obtained by dissolving a metal complex in a solvent. Examples of a metal constituting the metal complex include silver, copper, gold, aluminum, magnesium, tungsten, molybdenum, zinc, nickel, iron, platinum, tin, copper, and lead. Among these, from a perspective of electromagnetic wave-shielding properties, the metal constituting the metal complex preferably includes at least one selected from a group consisting of silver, gold, platinum, nickel, palladium, and copper and more preferably includes silver.

### <<Electric Configuration of Liquid Jetting Device 10>>

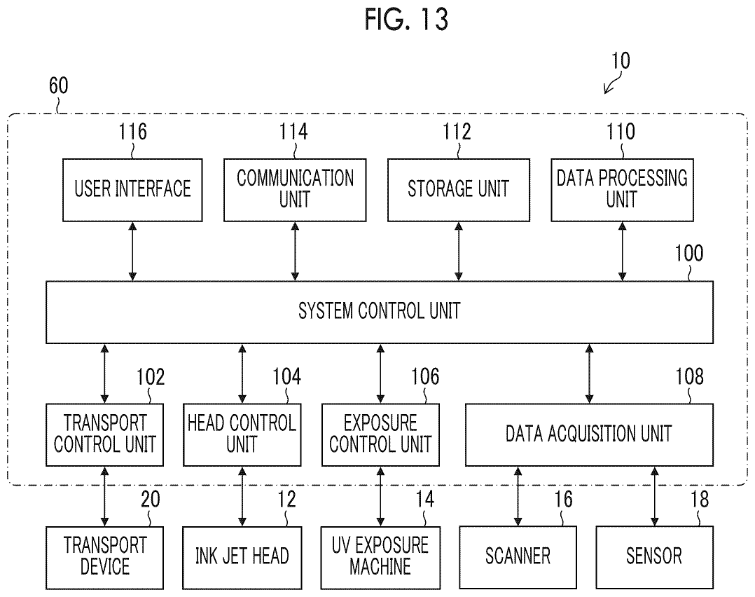

FIG. 13 is a functional block diagram showing an electric configuration of the liquid jetting device 10. As shown in FIG. 13, the liquid jetting device 10 comprises a control device 60. The control device 60 comprises a system control unit 100, a transport control unit 102, a head control unit 104, an exposure control unit 106, a data acquisition unit 108, a data processing unit 110, a storage unit 112, a communication unit 114, and a user interface 116. The control device 60 is composed of hardware and software of a computer.

The system control unit 100 transmits an instruction signal to each unit such as the transport control unit 102, the head control unit 104, the exposure control unit 106, the data acquisition unit 108, the data processing unit 110, the storage unit 112, the communication unit 114, and the user interface 116 and integrally controls an operation of the liquid jetting device 10.

The transport control unit 102 controls an operation of the transport device 20. That is, the transport control unit 102 controls the moving mechanism 24 so that the print substrate 1102 placed on the transport stage 22 is transported.

The data acquisition unit 108 acquires various types of data from the scanner 16, a sensor 18, an external device (not shown), and the like. The data acquisition unit 108 acquires, for example, printing data including conductive pattern data for forming the conductive pattern 1020 from an external device such as a host computer. In addition, the data acquisition unit 108 acquires read data from the scanner 16. The sensor 18 is shown as a representative of one or more sensors such as a temperature sensor, a pressure sensor, and a position detection sensor included in the liquid jetting device 10. The data acquisition unit 108 acquires sensor data from various types of sensors 18.

The data processing unit 110 includes a calculation unit that processes various types of data acquired via the data acquisition unit 108. The data processing unit 110 processes read data acquired via the scanner 16 to evaluate the jetting state of the ink jet head 12. In addition, the data processing unit 110 generates, for example, jetting data of a conductive ink from conductive pattern data. That is, the data processing unit 110 executes image processing, such as halftone processing, on the conductive pattern data and generates jetting data in which the position of a dot corresponding to the conductive pattern data and the size of the dot are defined. The jetting data may be dot data indicating the position of a dot to be printed.

The head control unit 104 controls jetting of the nozzle 162 of the ink jet head 12 based on jetting data corresponding to conductive pattern data. In addition, the head control unit 104 controls jetting of the nozzle 162 of the ink jet head 12 based on jetting data corresponding to data for printing a test pattern. The exposure control unit 106 controls the UV exposure machine 14. The exposure control unit 106 controls on/off of UV exposure, irradiation intensity of UV light, and the like.

The storage unit 112 is composed of a computer-readable medium including a memory and stores various data, various parameters, various programs, and the like used in controlling the liquid jetting device 10. The system control unit 100 applies various types of data and the like, which are stored in the storage unit 112, to control each unit of the liquid jetting device 10. The system control unit 100 and the head control unit 104 serve a role of a control unit that controls printing by the ink jet head 12.

The communication unit 114 includes a communication interface for communication with an external device. A communication type may be wireless communication or may be wired communication. The communication unit 114 may include elements of the data acquisition unit 108.

The user interface 116 includes an input device that receives an input of information from the user and a display device that displays various types of information.

### <<Configuration of Hardware of Control Device 60>>

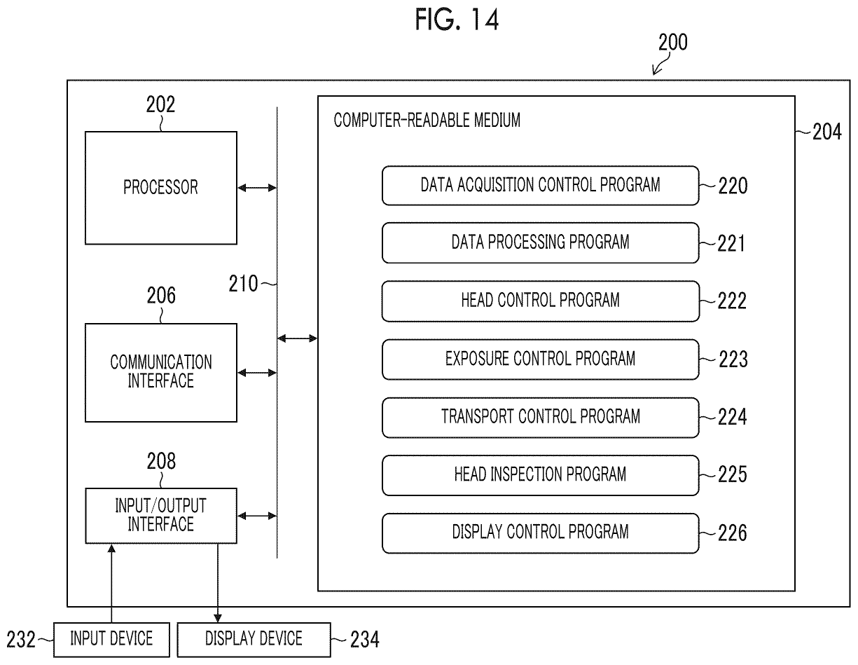

FIG. 14 is a block diagram showing a configuration example of hardware of an information processing apparatus 200 that functions as the control device 60. The information processing apparatus 200 is configured by a combination of hardware and software of a computer. The computer may be a server, a personal computer, a workstation, a tablet terminal, or the like and may be in any physical form. The information processing apparatus 200 comprises a processor 202, a computer-readable medium 204, a communication interface 206, an input/output interface 208, and a bus 210.

The processor 202 includes a central processing unit (CPU). The processor 202 may include a graphics processing unit (GPU). The processor 202 is connected to the computer-readable medium 204, the communication interface 206, and the input/output interface 208 via the bus 210.

The computer-readable medium 204 includes, for example, a random access memory (RAM) and a storage. The RAM is a memory that functions as a main memory. The storage is an auxiliary storage device. The storage may be, for example, a hard disk drive (HDD) device, a solid state drive (SSD) device, or a combination of a plurality thereof. In addition, the computer-readable medium 204 includes a read-only memory (ROM). A part or all of a storage region of the computer-readable medium 204 may be included in the processor 202. The computer-readable medium 204 functions as the storage unit 112 shown in FIG. 13.

The computer-readable medium 204 stores a program, data, or the like that realizes functions of a printer controller. The term “program” includes a concept of a program module. A data acquisition control program 220, a data processing program 221, a head control program 222, an exposure control program 223, a transport control program 224, a head inspection program 225, a display control program 226, and the like are stored in the computer-readable medium 204.

The data acquisition control program 220 is a program including a command that realizes a function of acquisition control of various types of data corresponding to the data acquisition unit 108 shown in FIG. 13. The data processing program 221 is a program including a command that realizes a processing function of various types of data corresponding to the data processing unit 110 shown in FIG. 13. The head control program 222 is a program including a command that realizes a function of ink jetting control corresponding to the head control unit 104 shown in FIG. 13. The exposure control program 223 is a program including a command that realizes a function of exposure corresponding to the exposure control unit 106 shown in FIG. 13.

The transport control program 224 is a program including a command that realizes a control function of the transport device 20 corresponding to the transport control unit 102 shown in FIG. 13. The head inspection program 225 is a program including a command that realizes a function of processing of analyzing a read image obtained from the scanner 16 and evaluating the jetting state of the ink jet head 12. The head inspection program 225 may be incorporated into the data processing program 221. The display control program 226 is a program including a command that realizes a function of generating a display signal necessary for a display output to a display device 234 and performing display control of the display device 234.

The processor 202 executes a command of a program stored in the computer-readable medium 204 to realize various types of control and processing. Some of the processing functions of the information processing apparatus 200 may be realized by using an integrated circuit represented by a digital signal processor (DSP) or a field programmable gate array (FPGA).

The communication interface 206 performs communication processing with an external device in a wired or a wireless communication manner to exchange information with the external device. The information processing apparatus 200 is connected to a communication line (not shown) via the communication interface 206. The communication line may be a local area network or a wide area network. The communication interface 206 functions as the communication unit 114 shown in FIG. 13. The communication interface 206 can function as the data acquisition unit 108 shown in FIG. 13.

The information processing apparatus 200 is connected to an input device 232 and the display device 234 via the input/output interface 208. The input device 232 is composed of, for example, a keyboard, a mouse, a multi-touch panel, another pointing device, a sound input device, or an appropriate combination thereof. The display device 234 is composed of, for example, a liquid crystal display, an organic electro-luminescence (OEL) display, a projector, or an appropriate combination thereof.

The input device 232 and the display device 234 may be integrally configured like a touch panel. The input device 232 and the display device 234 may be included in the information processing apparatus 200, or the information processing apparatus 200, the input device 232, and the display device 234 may be integrally configured.

In addition, the processing function of the information processing apparatus 200 is not limited to a case of being realized by one computer and may be realized by distributing processing using a plurality of computers.

### <<Example of Control Method of Liquid Jetting Device 10>>

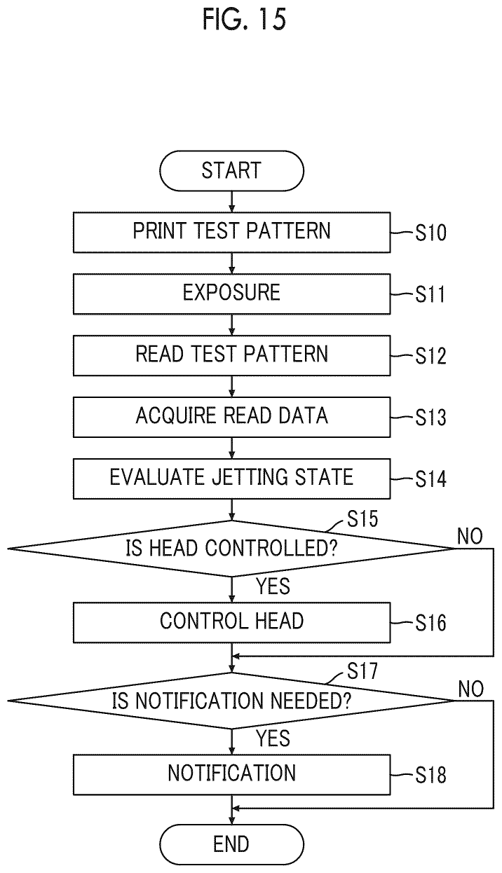

FIG. 15 is a flowchart showing an example of a jetting state evaluation method performed by the liquid jetting device according to embodiment 1. Steps of the jetting state evaluation method shown in FIG. 15 are realized as the processor 202 of the information processing apparatus 200 executes the head inspection program 225.

A test pattern printing step of step S10 is a step of printing a test pattern for inspecting the jetting state of the nozzle 162 which is the ink jet head. The test pattern printing step may be performed in the conductive ink printing step. In the test pattern printing step, the liquid jetting device 10 jets an ink from the plurality of nozzles 162 of the ink jet head 12 to the print substrate 1102 transported by the transport device 20 and prints the test pattern.

An exposure step of step S11 is a step of exposing a conductive ink by irradiating the test pattern printed on the print substrate 1102 with UV light. In the exposure step, the UV exposure machine 14 irradiates the test pattern printed on the print substrate 1102 transported by the transport device 20 with UV light. Through the exposure step, the conductive ink on the print substrate 1102 is colored, and printing results of the test pattern are brought into an observable state.

A test pattern reading step of step S12 is a step of reading the test pattern after exposure with the scanner 16. In the test pattern reading step, the scanner 16 images the test pattern after exposure, which is printed on the print substrate 1102 transported by the transport device 20, and acquires a read image.

A read data acquisition step of step S13 is a step in which the information processing apparatus 200 acquires read data including the read image of the test pattern read by the scanner 16.

A jetting state evaluation step of step S14 is a step of evaluating the jetting state of the nozzle 162 of the ink jet head 12 based on the read data. In the jetting state evaluation step, the information processing apparatus 200 analyzes the read image of the test pattern and generates inspection results related to the jetting state of the nozzle 162 of the ink jet head 12. The inspection results include, for example, information of a position in the ink jet head 12 of the nozzle 162 of which the jetting state is determined to be abnormal. Determination is normal or abnormal by the processor 202 as to whether the jetting state of the nozzle 162 is an example of evaluating the jetting state. In addition, inspection results including position information of an abnormal jetting nozzle are an example of evaluation results of the jetting state. The information processing apparatus 200 may output the inspection results to the external device via the communication interface 206.

A head control determination step of step S15 is a step of determining whether or not control of the ink jet head 12 is executed based on the inspection results acquired in the jetting state evaluation step. In the head control determination step, the processor 202 determines whether or not control of the ink jet head 12 with respect to an abnormal jetting nozzle is executed based on information such as presence or absence of the abnormal jetting nozzle and the number of abnormal jetting nozzles. In a case where a Yes determination is made as the determination results of step S15, the processor 202 proceeds to step S16 and performs control of the ink jet head 12.

A head control step of step S16 is a step of controlling of the ink jet head 12 based on the inspection results of the jetting state evaluation step. In the head control step, for example, the processor 202 stops jetting of an ink from the nozzle 162 of which the jetting state is determined to be abnormal. In addition, the processor 202 performs processing of correcting printing data such that a necessary ink amount is compensated by the nozzle 162 in the vicinity of the nozzle 162 which has stopped jetting. In addition, the processor 202 may forcibly stop the conductive ink printing step in a case where the number of nozzles 162 of which the jetting states are determined to be abnormal is larger than the reference value (threshold value). In addition, the processor 202 may automatically execute cleaning of the ink jet head 12 with a cleaning device (not shown).

In a case where a No determination is made as the determination results of step S15 or after step S16, the processor 202 proceeds to step S17.

A notification determination step of step S17 is a step of determining whether or not to make notification to the operator (user) based on the inspection results of the jetting state evaluation step. In the notification determination step, the processor 202 determines whether notification is necessary based on information such as presence or absence of an abnormal jetting nozzle and the number of abnormal jetting nozzles. In a case where a Yes determination is made as the determination results of step S17, the processor 202 proceeds to step S18 and makes notification.

A notification step of step S18 is a step of presenting information to the operator based on the inspection results of the jetting state evaluation step. In the notification step, for example, in a case where the number of nozzles 162 of which the jetting states are determined to be abnormal is determined to be larger than the reference value, the processor 202 may instruct the operator to stop the conductive ink printing step or may instruct the operator to perform cleaning of the ink jet head 12. Further, in a case where the jetting state is determined to be not restored even after cleaning of the ink jet head 12 is performed, the processor 202 may instruct the operator to replace the ink jet head 12. Presenting information including such an instruction to the operator is performed by displaying on the display device 234.

In the liquid jetting device 10 according to embodiment 1, the jetting state of the ink jet head 12 using a transparent metal complex ink can be evaluated, evaluation results are fed back to control of the ink jet head 12, and information is presented to the operator, so that a printing quality can be maintained and restored.

### Modification Example 1 of Embodiment 1

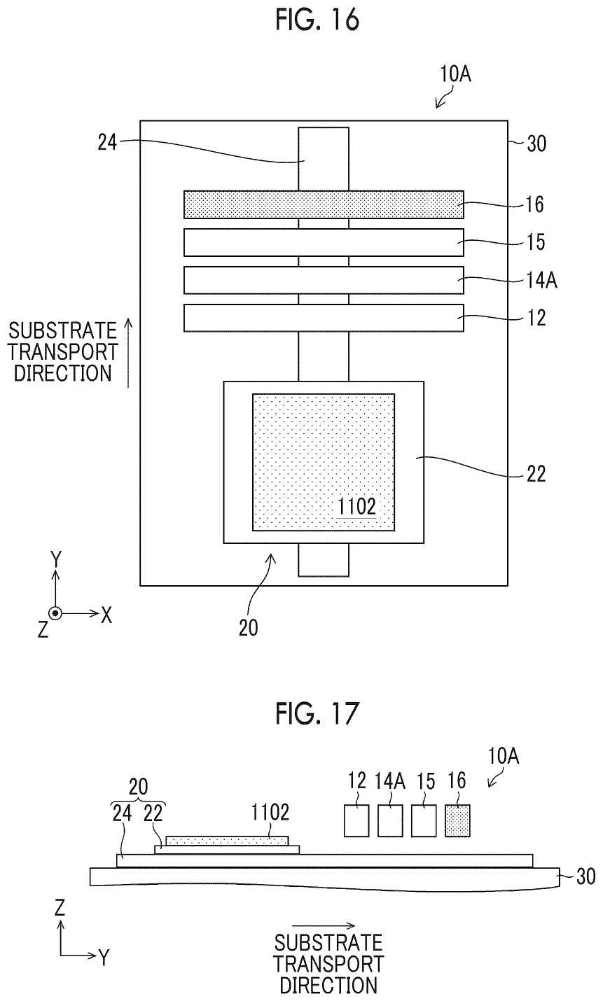

FIG. 16 is a plan view schematically showing a configuration of a liquid jetting device 10A according to a modification example of embodiment 1. FIG. 17 is a schematic side view of the liquid jetting device 10A viewed from the right direction of FIG. 16. A difference of the configuration of the liquid jetting device 10A shown in FIGS. 16 and 17 from the configuration described in FIGS. 4 and 5 will be described. Detailed description of the configuration of the liquid jetting device 10A shown in FIGS. 16 and 17 will be omitted with portions common to FIGS. 4 and 5 assigned with common reference numerals.

The liquid jetting device 10A comprises a first UV exposure machine 14A and a second UV exposure machine 15, instead of the UV exposure machine 14. The first UV exposure machine 14A is maintained in an output state where UV light is emitted at relatively weak irradiation intensity at all times, and a user pattern is brought into a state that can be cured to the minimum. On the other hand, the second UV exposure machine 15 exposes only a test pattern, and the test pattern is brought into a readable state. That is, control in which the second UV exposure machine 15 irradiates the test pattern with UV light and the output state is changed such that the user pattern is not irradiated with UV light is performed. Accordingly, an appropriate exposure amount of each of the test pattern and the user pattern can be realized only by on/off control of the second UV exposure machine 15 rather than performing minute adjustment of irradiation intensity using only one UV exposure machine 14. The first UV exposure machine 14A is an example of a “first exposure machine” in the present disclosure, and the second UV exposure machine 15 is an example of a “second exposure machine” in the present disclosure.

### Modification Example 2 of Embodiment 1

Without being limited to the single-pass type liquid jetting device 10 using the line type ink jet head 12, a multi-pass type (serial type) liquid jetting device that performs printing while reciprocating a short ink jet head in the X-direction may be adopted.

### Embodiment 2: Case of Dispenser Type

Although an example in which the ink jet head 12 is used as the liquid jetting head has been described in embodiment 1, a jetting type of the liquid jetting head is not limited to the ink jet type. An example in which a dispenser is used as the liquid jetting head will be described in embodiment 2.

In a print substrate manufacturing step, a dispenser is used instead of the ink jet type liquid jetting head in some cases and can be applied to the present invention also in this case. A manufacturing process in the print substrate manufacturing step is the same as in FIG. 2. Even with the dispenser type, an insulating ink or a conductive ink can be jetted as in the ink jet type.

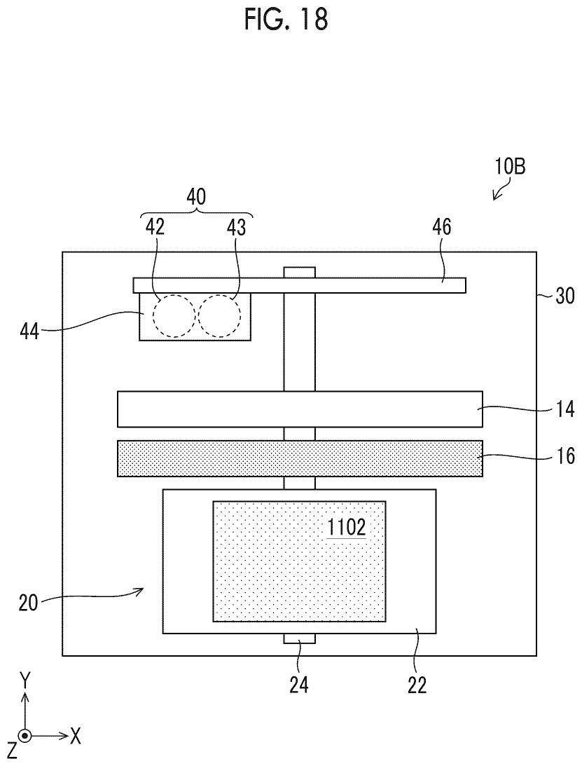

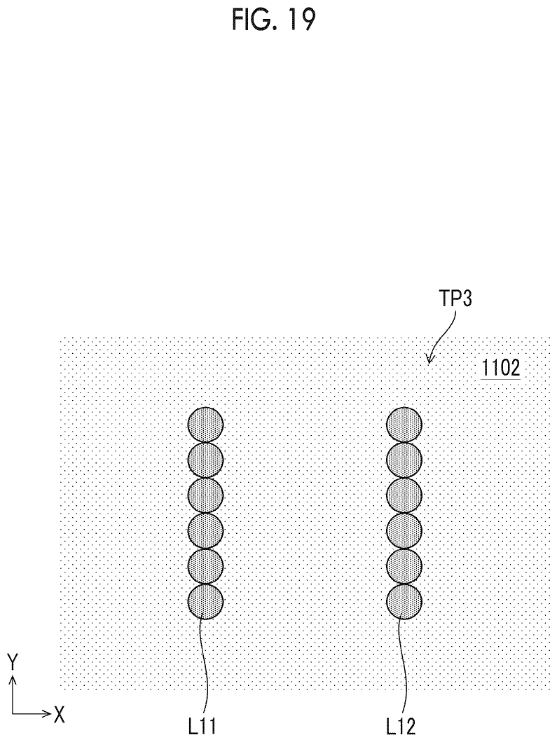

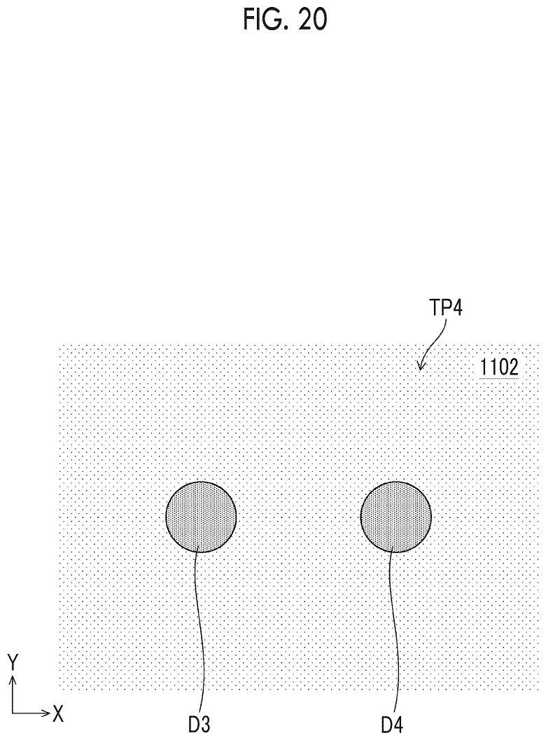

FIG. 18 is a plan view schematically showing a configuration of a liquid jetting device 10B according to embodiment 2. In FIG. 18, portions common to FIG. 4 will be assigned with common reference numerals, and detailed description thereof will be omitted. The liquid jetting device 10B comprises a dispenser printing unit that coats the print substrate 1102 with an insulating ink and a conductive ink, instead of the ink jet printing unit described in FIG. 4.

As shown in FIG. 18, the liquid jetting device 10B comprises a dispenser unit 40, a carriage 44, and a carriage shaft 46 that supports the carriage 44, instead of the ink jet head 12 of FIG. 4. The dispenser unit 40 includes an insulating ink dispenser 42 that jets an insulating ink and a conductive ink dispenser 43 that jets a conductive ink. Each of the insulating ink dispenser 42 and the conductive ink dispenser 43 comprises a nozzle (not shown) that jets an ink. One or a plurality of nozzles may be used. The conductive ink dispenser 43 is an example of the “liquid jetting head” in the present disclosure.

The carriage 44 fixes and supports the dispenser unit 40. The carriage 44 fixes and supports the insulating ink dispenser 42 and the conductive ink dispenser 43 such that the respective nozzles are directed in the −Z-direction. In addition, the carriage 44 fixes and supports the insulating ink dispenser 42 arranged on a −X-direction side and the conductive ink dispenser 43 arranged on a +X-direction side.

The carriage shaft 46 is disposed parallel to the X-direction and supports the carriage 44 to be movable in the X-direction. A mechanism that moves the carriage 44 may be, for example, a ball screw drive mechanism or a mechanism using a linear motor.

In the insulating ink printing step, the liquid jetting device 10B configured as described above forms the insulating coating 1022 and the insulating pattern 1024 on the print substrate 1102 by transporting the print substrate 1102 in the +Y-direction and jetting an insulating ink from the nozzles of the insulating ink dispenser 42 while moving the carriage 44 in the +X-direction and the −X-direction with respect to the transported wiring board 1002.

In addition, in the conductive ink printing step, the liquid jetting device 10B forms the conductive pattern 1020 on the print substrate 1102 by transporting the print substrate 1102 in the +Y-direction and jetting a conductive ink from the nozzles of the conductive ink dispenser 43 while moving the carriage 44 in the +X-direction and the −X-direction with respect to the transported print substrate 1102.

Jetting states of the nozzles of the insulating ink dispenser 42 and the conductive ink dispenser 43 deteriorate in some cases as in the ink jet head 12. Thus, in embodiment 2, a test pattern for inspecting the jetting state of the dispenser unit 40 is printed on the print substrate 1102 by the insulating ink dispenser 42 and the conductive ink dispenser 43, and the jetting states are evaluated under the same method as the method described in embodiment 1. A control device of the liquid jetting device 10B may have the same configuration as the control device 60 described in embodiment 1.

### <<Example of Test Pattern>>

FIGS. 19 and 20 show an example of a test pattern printed on the print substrate 1102 by the dispenser type liquid jetting device 10B shown in FIG. 18.

FIG. 19 is a view showing an example of a test pattern which is a line pattern. In a test pattern TP3 shown in FIG. 19, a line L11 is an insulating ink line printed by the nozzles of the insulating ink dispenser 42, and a line L12 is a conductive ink line printed by the nozzles of the conductive ink dispenser 43. The print substrate 1102 is transported in the Y-direction by the transport device 20, the dispenser unit 40 and the print substrate 1102 are relatively moved, and an ink is jetted from each of the insulating ink dispenser 42 and the conductive ink dispenser 43. Accordingly, the line L11 and the line L12 can be printed.

FIG. 20 is a view showing an example of a test pattern which is a dot pattern. In a test pattern TP4 shown in FIG. 20, a dot D3 is an insulating ink dot printed by the nozzles of the insulating ink dispenser 42, and a dot D4 is a conductive ink dot printed by the nozzles of the conductive ink dispenser 43.

After printing a test pattern such as the test pattern TP3 of FIG. 19 and/or the test pattern TP4 of FIG. 20, the test pattern is exposed by the UV exposure machine 14 and is observed using the scanner 16. Accordingly, a state of a dispenser of which a jetting state is abnormal can be found.

The liquid jetting device 10B can determine whether or not a dispenser performs stable jetting while printing a straight line from reading results of the test pattern TP3 formed by jetting the line shown in FIG. 19 as a test pattern. In addition, by printing the dot shown in FIG. 20, the liquid jetting device 10B can determine, from reading results of the test pattern TP4, whether or not liquid droplets of an ink are normally jetted from the insulating ink dispenser 42 and the conductive ink dispenser 43.

Through such inspection, information of the insulating ink dispenser 42 and the conductive ink dispenser 43 of which jetting states are determined to be abnormal is transmitted to the dispenser printing unit. Then, in a case of being determined to be abnormal, for example, as in embodiment 1, the liquid jetting device 10B may perform cleaning processing on the insulating ink dispenser 42 and/or the conductive ink dispenser 43 or may instruct the user to perform cleaning processing, replacement of the nozzle unit, or the like.

Although the same dispenser printing unit is configured to perform coating of an insulating ink and a conductive ink in FIG. 18, a printing unit that performs coating of the insulating ink and a printing unit that performs coating of the conductive ink may be separated. For example, a liquid jetting device that comprises a dispenser jetting an insulating ink and a liquid jetting device that comprises a dispenser jetting a conductive ink may be configured as devices different from each other, and the liquid jetting devices different from each other may perform coating of the insulating ink and the conductive ink.

### Embodiment 3: Case of Spray Type

In embodiment 3, an example of using a spray as the liquid jetting head will be described. In the print substrate manufacturing step, the spray is used instead of the ink jet type liquid jetting head in some cases and can be applied to the present invention also in this case. A manufacturing process in the print substrate manufacturing step is the same as in FIG. 2. Even with the spray type, an insulating ink or a conductive ink can be jetted as in the ink jet type.

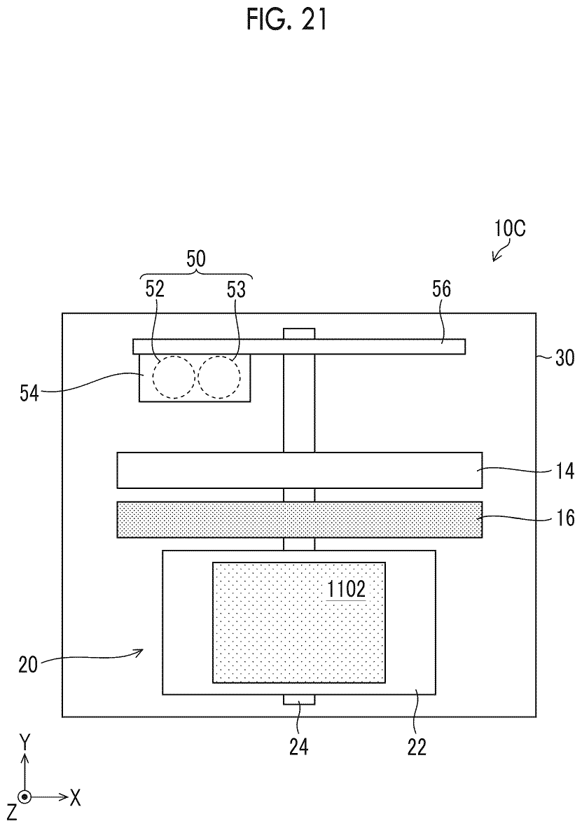

FIG. 21 is a plan view schematically showing a configuration of a liquid jetting device 10C according to embodiment 3. In FIG. 21, portions common to FIG. 4 will be assigned with common reference numerals, and detailed description thereof will be omitted. The liquid jetting device 10C comprises a spray printing unit that coats the print substrate 1102 with an insulating ink and a conductive ink, instead of the ink jet printing unit described in FIG. 4.

As shown in FIG. 21, the liquid jetting device 10C comprises a spray unit 50, a carriage 54, and a carriage shaft 56 that supports the carriage 54, instead of the ink jet head 12 of FIG. 4. The liquid jetting device 10C is configured such that the dispenser unit 40 of FIG. 18 is replaced with the spray unit 50.

The spray unit 50 includes an insulating ink spray 52 that jets an insulating ink and a conductive ink spray 53 that jets a conductive ink. Each of the insulating ink spray 52 and the conductive ink spray 53 comprises a nozzle (not shown) that atomizes and jets (sprays) an ink. One or a plurality of nozzles may be used. The conductive ink spray 53 is an example of the “liquid jetting head” in the present disclosure.

The carriage 54 fixes and supports the spray unit 50. The carriage 54 fixes and supports the insulating ink spray 52 and the conductive ink spray 53 such that the respective nozzles are directed in the −Z-direction. In addition, the carriage 54 fixes and supports the insulating ink spray 52 arranged on the −X-direction side and the conductive ink spray 53 arranged on the +X-direction side.

The carriage shaft 56 is disposed parallel to the X-direction and supports the carriage 54 to be movable in the X-direction. A mechanism that moves the carriage 54 may be, for example, a ball screw drive mechanism or a mechanism using a linear motor.

In the insulating ink printing step, the liquid jetting device 10C configured as described above forms the insulating coating 1022 and the insulating pattern 1024 on the print substrate 1102 by transporting the print substrate 1102 in the +Y-direction and jetting an insulating ink from the nozzles of the insulating ink spray 52 while moving the carriage 54 in the +X-direction and the −X-direction with respect to the transported print substrate 1102.

In addition, in the conductive ink printing step, the liquid jetting device 10C forms the conductive pattern 1020 on the print substrate 1102 by transporting the print substrate 1102 in the +Y-direction and jetting a conductive ink from the nozzles of the conductive ink spray 53 while moving the carriage 54 in the +X-direction and the −X-direction with respect to the transported print substrate 1102.

Jetting states of the nozzles of the insulating ink spray 52 and the conductive ink spray 53 deteriorate in some cases as in the ink jet head 12. Thus, in embodiment 3, a test pattern for inspecting the jetting state of the spray unit 50 is printed on the print substrate 1102 by the insulating ink spray 52 and the conductive ink spray 53, and the jetting states are evaluated with the same method as the method described in embodiment 1 applied. A control device of the liquid jetting device 10C may have the same configuration as the control device 60 described in embodiment 1.

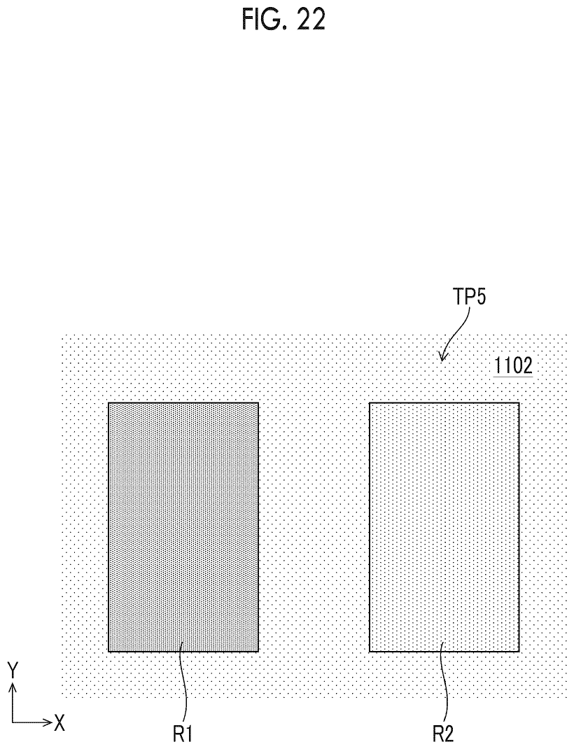

FIG. 22 is a view showing an example of a test pattern for inspecting the jetting state of the spray unit 50. In a test pattern TP5 shown in FIG. 22, a region R1 is an insulating ink region where printing is performed with an insulating ink jetted from the nozzles of the insulating ink spray 52, and a region R2 is a conductive ink region where printing is performed with a conductive ink jetted from the nozzles of the conductive ink spray 53. The region R1 and the region R2 may be rectangular regions having constant widths in the X-direction and the Y-direction, respectively.

After printing the test pattern TP5 shown in FIG. 22, the test pattern TP5 is exposed by the UV exposure machine 14 and is observed with the scanner 16. Thereby, the jetting state can be found to be an abnormal spray state.

Through such inspection, information of the insulating ink spray 52 and/or the conductive ink spray 53 determined to be in an abnormal spraying state (the jetting state is abnormal) is transmitted to the spray printing unit. Then, in a case of being determined to be abnormal, for example, as in embodiment 1, the liquid jetting device 10C may perform cleaning processing of the insulating ink spray 52 and/or the conductive ink spray 53 or may instruct the operator to perform cleaning processing and/or replacement of a component.

Although the liquid jetting device 10C is configured to perform coating with an insulating ink and a conductive ink using the spray unit 50 comprising the insulating ink spray 52 and the conductive ink spray 53, a printing unit that performs coating with the insulating ink and a printing unit that performs coating with the conductive ink may be separated. For example, a liquid jetting device that comprises a spray jetting an insulating ink and a liquid jetting device that comprises a spray jetting a conductive ink may be configured as devices different from each other, and the liquid jetting devices different from each other may perform coating of the insulating ink and the conductive ink.

### <Program Operating Computer>

A program causing a computer to realize some or all of the processing functions of the control device 60 can be recorded on a computer-readable medium which is an optical disk, a magnetic disk, or a tangible non-transitory information storage medium other than a semiconductor memory, and the program can be provided through the information storage medium.

In addition, instead of an aspect of providing the program by storing the program in such a non-transitory tangible computer-readable medium, a program signal can also be provided as a download service using an electric communication line such as the Internet.

Some or all of the processing functions of the control device 60 may be realized by cloud computing or can also be provided as software as a service (SasS).

### <Hardware Configuration of Each Processing Unit>

Hardware structures of processing units executing various types pf processing, such as the system control unit 100, the transport control unit 102, the head control unit 104, the exposure control unit 106, the data acquisition unit 108, and the data processing unit 110 of the control device 60 are, for example, various types of processors as follows.

The various types of processors include a CPU that is a general-purpose processor functioning as various types of processing units by executing a program, a GPU that is a processor specialized for image processing, a programmable logic device (PLD) that is a processor of which a circuit configuration can be changed after manufacturing, such as a field programmable gate array (FPGA), and a dedicated electric circuit that is a processor having a circuit configuration specifically designed to execute specific processing, such as an application specific integrated circuit (ASIC).

One processing unit may be composed of one of the various types of processors or may be composed of two or more processors of the same type or different types. For example, one processing unit may be composed of a plurality of FPGAs, a combination of a CPU and an FPGA, or a combination of a CPU and a GPU. In addition, one processor may constitute a plurality of processing units. As an example in which one processor constitute a plurality of processing units, first, there is a form in which, as represented by computers such as a client and a server, one processor is configured by combining one or more CPUs and software, and the processor functions as a plurality of processing units. Second, there is a form in which, as represented by a system on chip (SoC) and the like, a processor that realizes functions of the entire system including a plurality of processing units with one integrated circuit (IC) chip is used. As described above, the various types of processing units are composed of one or more of the various types of processors used as a hardware structure.

Further, as the hardware structure of the various processors, more specifically, an electric circuit (circuitry) in which circuit elements such as semiconductor elements are combined is used.

### Other Application Examples

Although an example of printing on the print substrate has been described in each of the embodiments described above, without being limited to the print substrate, the technique of the present disclosure can be applied to printing on substrates of various types, applications, and materials. In addition, the substrate is not limited to a single sheet substrate which is cut one by one and may be a roll-shaped (web-shaped) continuous substrate.

### Combination of Embodiments and Modification Examples

Matters described in the configurations or the modification examples described in the embodiments can be used in combination as appropriate, and some of the matters can be replaced.

### Others

The technical scope of the present invention is not limited to the scope described in the embodiments described above. The configuration of each embodiment can be subjected to various modifications without departing from the gist of the technical idea of the present disclosure.

### EXPLANATION OF REFERENCES

10, 10A, 10B, 10C: liquid jetting device
12: ink jet head
14: UV exposure machine
14A: first UV exposure machine
15: second UV exposure machine
16: scanner
18: sensor
20: transport device
22: transport stage
24: moving mechanism
30: base plate
40: dispenser unit
42: insulating ink dispenser
43: conductive ink dispenser
44: carriage
46: carriage shaft
50: spray unit
52: insulating ink spray
53: conductive ink spray
54: carriage
56: carriage shaft
60: control device
100: system control unit
102: transport control unit
104: head control unit
106: exposure control unit
108: data acquisition unit
110: data processing unit
112: storage unit
114: communication unit
116: user interface
148, 148-1, 148-2, 148-3: nozzle surface
150-1, 150-2, 150-3: head module
152: support frame
154: flexible substrate
156: dummy plate
156A: surface
158-i: nozzle disposition portion
160: nozzle line
162: nozzle
164: ejector
166: pressure chamber
168: piezoelectric element
170: nozzle flow passage
172: individual supply passage
174: supply-side common branch flow passage
176: vibration plate
178: individual electrode
180: piezoelectric body
182: cover plate
184: movable space
200: information processing apparatus
202: processor
204: computer-readable medium
206: communication interface
208: input/output interface
210: bus
220: data acquisition control program
221: data processing program
222: head control program
223: exposure control program
224: transport control program
225: head inspection program
226: display control program
232: input device
234: display device
1000: print substrate
1002: wiring board
1004: component mounting surface
1006: IC
1006A: side surface
1006B: back surface
1006C: upper surface
1008: resistor
1008A: resistance array
1009: electrode
1010: capacitor
1020: conductive pattern
1022: insulating coating
1024: insulating pattern
1030: substrate-side electrode
1032: element-side electrode
1034: solder bump
1102: print substrate
1110: user pattern printing region
1120: test pattern printing region
TP1, TP2, TP3, TP4, TP5: test pattern
D1, D2, D3, D4: dot
L1, L2: line
L11, L12: line
R1, R2: region
S10 to S18: step of jetting state evaluation method

What is claimed is:

1. A liquid jetting device comprising:
a liquid jetting head that jets a metal complex ink;
a relative moving mechanism that relatively moves the liquid jetting head and a substrate;
an exposure machine that exposes the metal complex ink applied on the substrate; and
at least one processor,
wherein the at least one processor is configured to:
form a first pattern on the substrate by causing the metal complex ink to be jetted from the liquid jetting head;
acquire a reading result obtained by reading the first pattern using an observation device after exposing the first pattern using the exposure machine; and
evaluate a jetting state of the liquid jetting head from the reading result.

2. The liquid jetting device according to claim 1,
wherein the first pattern is a test pattern for inspecting the jetting state of the liquid jetting head.

3. The liquid jetting device according to claim 1,
wherein an exposure amount of the first pattern by the exposure machine is less than 500 mJ/cm².

4. The liquid jetting device according to claim 1,
wherein an exposure amount of the first pattern by the exposure machine is 300 mJ/cm² or less.

5. The liquid jetting device according to claim 1,
wherein the at least one processor is configured to:
form a second pattern different from the first pattern by causing the metal complex ink to be jetted from the liquid jetting head.

6. The liquid jetting device according to claim 5,
wherein the second pattern is a user pattern that is a pattern required for printing by a user.

7. The liquid jetting device according to claim 5,
wherein an exposure amount of the first pattern by the exposure machine is larger than an exposure amount of the second pattern by the exposure machine.

8. The liquid jetting device according to claim 5,
wherein exposure of the second pattern by the exposure machine is an exposure amount that is ⅕ of an exposure amount of the first pattern by the exposure machine or less.

9. The liquid jetting device according to claim 5,
wherein exposure of the second pattern by the exposure machine is an exposure amount to an extent that spread of the metal complex ink on the substrate is capable of being suppressed.

10. The liquid jetting device according to claim 5,
wherein an exposure amount of the second pattern by the exposure machine is 30 mJ/cm² or more and 100 mJ/cm² or less.

11. The liquid jetting device according to claim 5,
wherein the exposure machine includes a first exposure machine and a second exposure machine,
the first exposure machine maintains the same output state and exposes both the first pattern and the second pattern, and
the second exposure machine changes the output state and exposes only the first pattern among the first pattern and the second pattern.

12. The liquid jetting device according to claim 5,
wherein the second pattern is formed on the same substrate as the substrate on which the first pattern is formed.

13. The liquid jetting device according to claim 5,
wherein the first pattern is formed in a case of the relative movement before formation of the second pattern.

14. The liquid jetting device according to claim 1,
wherein the first pattern is formed in a region of the substrate, which is excised in a case of cutting the substrate into individual pieces.

15. The liquid jetting device according to claim 5,
wherein a first substrate that is the substrate on which the first pattern is formed and a second substrate on which the second pattern is formed are individual substrates, respectively.

16. The liquid jetting device according to claim 1,
wherein a b* value representing chromaticity of a metal in a state where the metal is precipitated by exposing the metal complex ink is |b*|<20.

17. The liquid jetting device according to claim 1,
wherein an a* value representing chromaticity of a metal in a state where the metal is precipitated by exposing the metal complex ink is |a*|<20.

18. The liquid jetting device according to claim 1,
wherein an L* value representing brightness of a metal in a state where the metal is precipitated by exposing the metal complex ink is 40 or more.

19. The liquid jetting device according to claim 1,
wherein a difference in an L* value representing brightness of each of a metal in a state where the metal is precipitated by exposing the metal complex ink and the substrate is 10 or more.

20. The liquid jetting device according to claim 1,
wherein an L* value representing brightness of the substrate is 30 or less.

21. The liquid jetting device according to claim 1,
wherein reflectivity of a metal in a state where the metal is precipitated by exposing the metal complex ink is 40% or more in a visible light range.

22. The liquid jetting device according to claim 1,
wherein the at least one processor is configured to:
perform at least one of control of the liquid jetting head or presenting of information based on an evaluation result of the jetting state.

23. The liquid jetting device according to claim 1,
wherein the exposure machine generates ultraviolet light.

24. A jetting state evaluation method comprising:
relatively moving a liquid jetting head and a substrate;
forming a first pattern on the substrate by jetting a metal complex ink from the liquid jetting head and applying the metal complex ink to the substrate;
exposing the first pattern formed on the substrate;
reading the first pattern using an observation device after exposing the first pattern; and
acquiring a reading result of the first pattern and evaluating a jetting state of the liquid jetting head from the reading result by at least one processor.

25. An information processing apparatus comprising:
at least one processor; and
at least one memory that stores a command for executing the at least one processor,
wherein the at least one processor is configured to:
acquire a reading result obtained by reading a first pattern formed on a substrate by applying a metal complex ink jetted from a liquid jetting head using an observation device after exposing the first pattern; and
evaluate a jetting state of the liquid jetting head from the reading result.

26. A manufacturing method of a print substrate comprising:
relatively moving a liquid jetting head and a print substrate;
forming a first pattern on the print substrate by jetting a metal complex ink from the liquid jetting head and applying the metal complex ink to the print substrate;
exposing the metal complex ink applied to the print substrate;
reading the first pattern using an observation device after exposing the first pattern;
acquiring a reading result of the first pattern and evaluating a jetting state of the liquid jetting head from the reading result by at least one processor;
performing at least one of control of the liquid jetting head or presenting of information based on an evaluation result of the jetting state by the at least one processor; and
forming a second pattern different from the first pattern on the print substrate by jetting the metal complex ink from the liquid jetting head and applying the metal complex ink to the print substrate.
